(19) United States
(12) Patent Application Publication
(10) Pub. No.: US 2025/0151266 A1
(43) Pub. Date: May 8, 2025

(54) INTEGRATED CIRCUIT INCLUDING ONE-TIME PROGRAMMABLE BIT CELL

(71) Applicant: SAMSUNG ELECTRONICS CO., LTD., Suwon-si (KR)

(72) Inventors: Hyojoon An, Suwon-si (KR); Seungkwon Lee, Suwon-si (KR)

(21) Appl. No.: 18/781,217

(22) Filed: Jul. 23, 2024

(30) Foreign Application Priority Data
Nov. 7, 2023 (KR) 10-2023-0153102

(51) Int. Cl. H10B 20/25

(52) U.S. Cl. CPC H10B 20/25

(57) ABSTRACT

An integrated circuit includes a one-time programmable (OTP) bit cell including a program transistor and a read transistor arranged on an active region extending on a front side of a substrate in a first direction, a first backside gate contact penetrating the substrate in a vertical direction and overlapped by the active region, a backside wiring layer arranged on a backside of the substrate and connected to a first gate of the program transistor via the first backside gate contact to transfer a program word line signal to the first gate, and a front side wiring layer arranged above the front side of the substrate and including a first front side wiring pattern connected to a second gate of the read transistor to transfer a read word line signal to the second gate.

### CROSS-REFERENCE TO RELATED APPLICATION

This application claims priority under 35 U.S.C. § 119 to Korean Patent Application No. 10-2023-0153102, filed on Nov. 7, 2023 in the Korean Intellectual Property office, the disclosure of which is incorporated by reference herein in its entirety.

### BACKGROUND

Due to the demand for a high degree of integration and the development of semiconductor processes, the width, spacing, and/or height of wirings included in integrated circuits may be reduced, and thus, the influence of parasitic components of the wirings may be increased. In addition, the power voltage of the integrated circuit may be decreased for reduced power consumption and high operating speed, and accordingly, the effect of parasitic components of the wirings on the integrated circuit may become significant.

### SUMMARY

Some aspects of this disclosure provide integrated circuits with an improved power performance area (PPA), and method of designing the integrated circuits by implementing a one-time programmable (OTP) bit cell by utilizing a front side wiring layer and a backside wiring layer.

According to some implementations, there is provided an integrated circuit including a one-time programmable (OTP) bit cell including a program transistor and a read transistor arranged on an active region extending on a front side of a substrate in a first direction, a first backside gate contact penetrating the substrate in a vertical direction and overlapped by the active region, a backside wiring layer arranged on a backside of the substrate, and connected to a first gate of the program transistor via the first backside gate contact to transfer a program word line signal to the first gate, and a front side wiring layer arranged above the front side of the substrate, and including a first front side wiring pattern connected to a second gate of the read transistor to transfer a read word line signal to the second gate.

According to some implementations, there is provided an integrated circuit including a one-time programmable (OTP) bit cell including a program transistor and a read transistor arranged on an active region extending on a front side of a substrate in a first direction, a front side wiring layer arranged above the front side of the substrate, and including a first front side wiring pattern connected to a first gate of the program transistor to transfer a program word line signal to the first gate, a first backside gate contact penetrating the substrate in a vertical direction and overlapped by the active region, and a backside wiring layer arranged on a backside of the substrate, and connected to a second gate of the read transistor via the first backside gate contact to transfer a read word line signal to the second gate.

According to some implementations, there is provided an integrated circuit including a one-time programmable (OTP) bit cell including a program transistor and a read transistor arranged on an active region extending on a front side of a substrate in a first direction, a front side wiring layer arranged above the front side of the substrate, the front side wiring layer including a first front side wiring pattern connected to a first gate of the program transistor to transfer a program word line signal to the first gate and a second front side wiring pattern connected to a second gate of the read transistor to transfer a read word line signal to the second gate, a through via extending in a vertical direction and penetrating the substrate, and a backside wiring layer arranged on a backside of the substrate, and connected to the first front side wiring pattern via the through via.

### BRIEF DESCRIPTION OF THE DRAWINGS

Implementations will be understood from the following detailed description taken in conjunction with the accompanying drawings in which:

FIG. 1 illustrates a layout of an integrated circuit according to some implementations;

FIG. 2A is a plan view of an example of a front side wiring layer of the integrated circuit of FIG. 1, according to some implementations;

FIG. 2B is a plan view of an example of a backside wiring layer of the integrated circuit of FIG. 1, according to some implementations;

FIG. 3 is a block diagram of a memory device according to some implementations;

FIG. 4 is a circuit diagram of a cell array according to some implementations;

FIG. 5 is a circuit diagram of a one-time programmable (OTP) bit cell according to some implementations;

FIG. 6A is a cross-sectional view of the integrated circuit of FIG. 1 taken along line X1 -X1′ in FIG. 1, according to some implementations;

FIG. 6B is a cross-sectional view of the integrated circuit of FIG. 1 taken along line X2 -X2′ in FIG. 1, according to some implementations;

FIG. 6C is a cross-sectional view of the integrated circuit of FIG. 1 taken along line X3 -X3′ in FIG. 1, according to some implementations;

FIG. 7 illustrates a layout of an integrated circuit according to some implementations;

FIG. 8A is a cross-sectional view of the integrated circuit of FIG. 7 taken along line X4 -X4′ in FIG. 7, according to some implementations;

FIG. 8B is a cross-sectional view of the integrated circuit of FIG. 7 taken along line X5 -X5′ in FIG. 7, according to some implementations;

FIG. 9 illustrates a layout of an integrated circuit according to some implementations;

FIG. 10A is a cross-sectional view of the integrated circuit of FIG. 9 taken along line X6 -X6′ in FIG. 9, according to some implementations;

FIG. 10B is a cross-sectional view of the integrated circuit of FIG. 9 taken along line X7 -X7′ in FIG. 9, according to some implementations;

FIG. 11 illustrates a layout of an integrated circuit according to some implementations;

FIG. 12 illustrates a layout of an integrated circuit according to some implementations;

FIG. 13A is a cross-sectional view of the integrated circuit of FIG. 12 taken along line X8 -X8′ in FIG. 12, according to some implementations;

FIG. 13B is a cross-sectional view of the integrated circuit of FIG. 12 taken along line X9 -X9′ in FIG. 12, according to some implementations;

FIG. 14 illustrates a layout of an integrated circuit according to some implementations;

FIG. 15 is a cross-sectional view of the integrated circuit of FIG. 14 taken along line X10-X10′ in FIG. 14, according to some implementations;

FIG. 16 illustrates a layout of an integrated circuit according to some implementations;

FIG. 17 is a cross-sectional view of the integrated circuit of FIG. 16 taken along line X11-X11′ in FIG. 16, according to some implementations;

FIGS. 18A through 18D are perspective views of examples of devices according to some implementations;

FIG. 19 is a flowchart illustrating a method of manufacturing an integrated circuit, according to some implementations;

FIG. 20 is a block diagram of a system-on-chip according to some implementations; and

FIG. 21 is a block diagram of a computing system including a memory for storing a program, according to some implementations.

### DETAILED DESCRIPTION

Hereinafter, various examples are described in detail with reference to the accompanying drawings. Identical reference numerals are used for the same constituent elements in the drawings, and duplicate descriptions thereof are omitted.

As used herein, the X-axis direction may be referred to as a first horizontal direction or a first direction, the Y-axis direction may be referred to as a second horizontal direction or a second direction, and the Z-axis direction may be referred to as a vertical direction. A plane formed by the X-axis and the Y-axis may be referred to as a horizontal plane, components arranged in the +Z-axis direction relative to other components may be referred to as being on the other components, and components arranged in the −Z-axis direction relative to other components may be referred to as being under the other components.

An integrated circuit may be designed by arranging a plurality of standard cells. A standard cell may be a unit of a layout of an integrated circuit, and may also be referred to as a “cell” according to some implementations. A standard cell may be designed to include a plurality of transistors for performing a pre-defined function. A standard cell method may include preparing in advance standard cells having various functions, and combining standard cells to design a dedicated large-scale integrated circuit tailored to the specifications of customers or users. A standard cell may be registered in a standard cell library after the design and verification of a standard cell is performed in advance, and by performing a logical design, placement, and routing by using computer aided design (CAD), an integrated circuit may be designed. When this integrated circuit is designed, by reducing lengths of wirings and/or vias and/or reducing routing complexity, performance of the integrated circuit may be further improved.

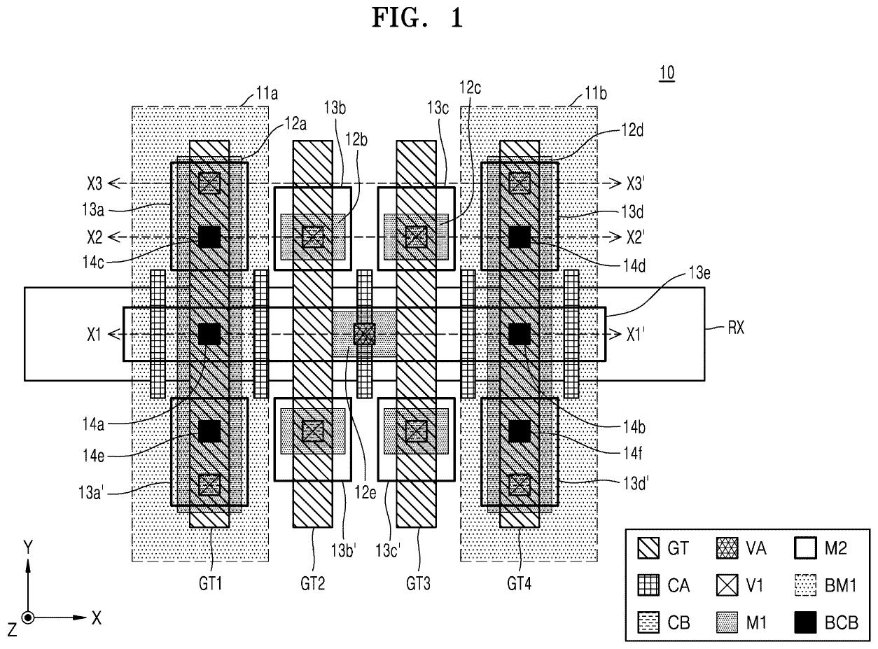

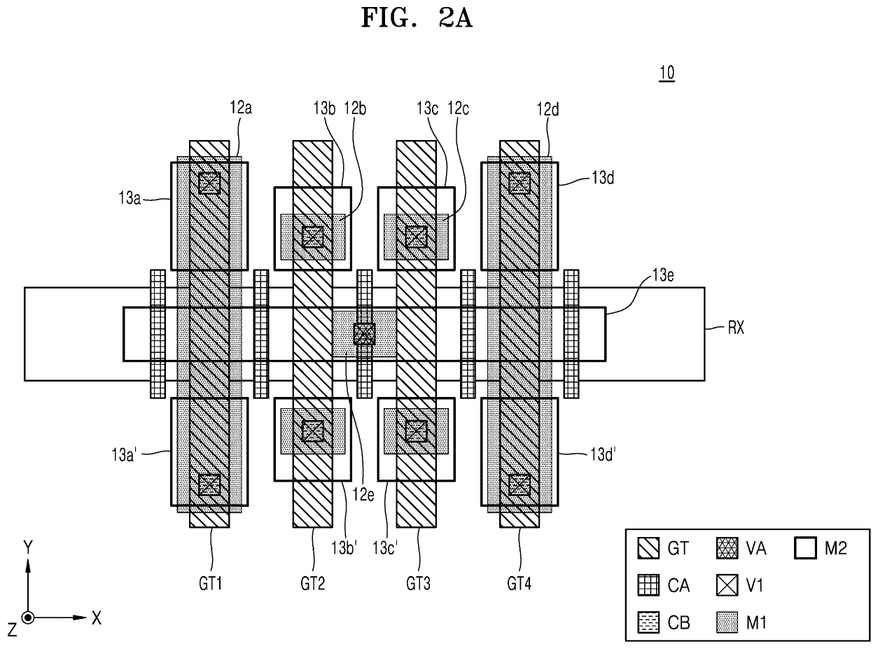

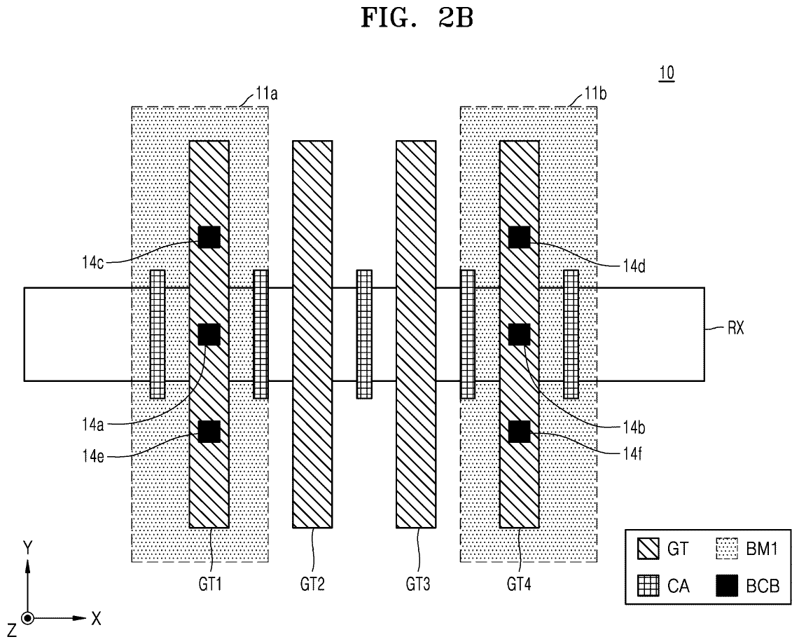

FIG. 1 illustrates a layout of an integrated circuit 10 according to some implementations. FIG. 2A illustrates a front side wiring layer of the integrated circuit 10 of FIG. 1, according to some implementations. FIG. 2B illustrates a backside wiring layer of the integrated circuit 10 of FIG. 1, according to some implementations.

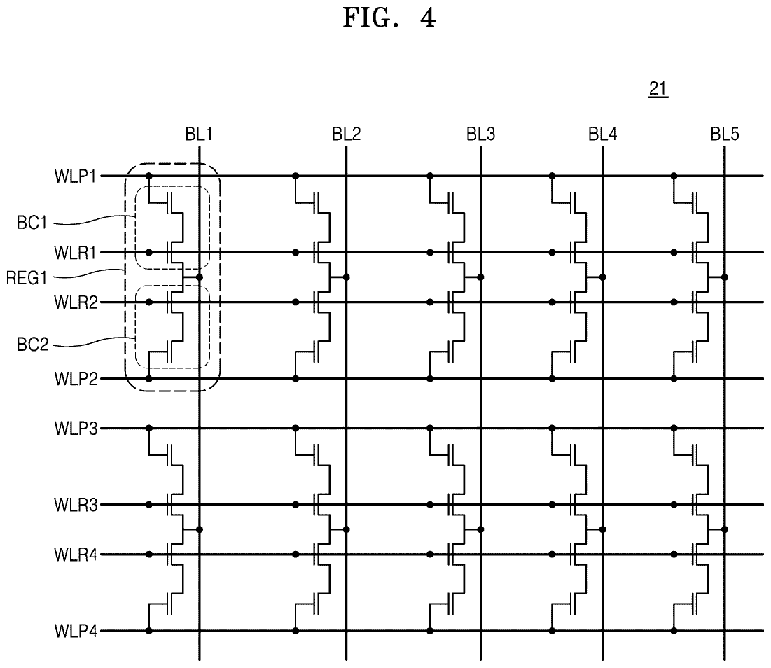

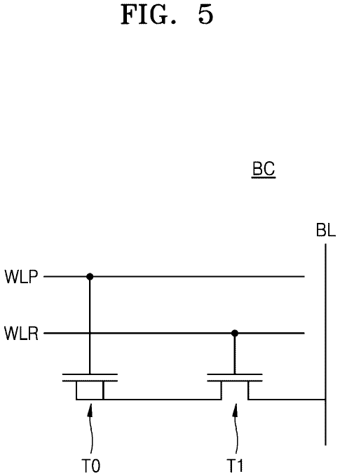

Referring to FIGS. 1 and 2A-2B, the integrated circuit 10 may include an active region RX, gate lines GT, source/drain contacts CA, gate contacts CB, first vias VA, second vias V1, a first front side wiring layer M1, a second front side wiring layer M2, a backside wiring layer BM1, and backside gate contacts BCB. According to some implementations, the first and second front side wiring layers M1 and M2 may be comprehensively referred to as “front side wiring layers”. For example, the gate lines GT, gate contacts CB, the backside gate contacts BCB, source/drain contacts CA, and source/drain regions on the active region RX may constitute a memory cell, for example, a one-time programmable (OTP) bit cell (for example, a bit cell (BC) in FIG. 5). For example, the integrated circuit 10 of FIG. 1 may correspond to an implementation of a first region REG1 in FIG. 4.

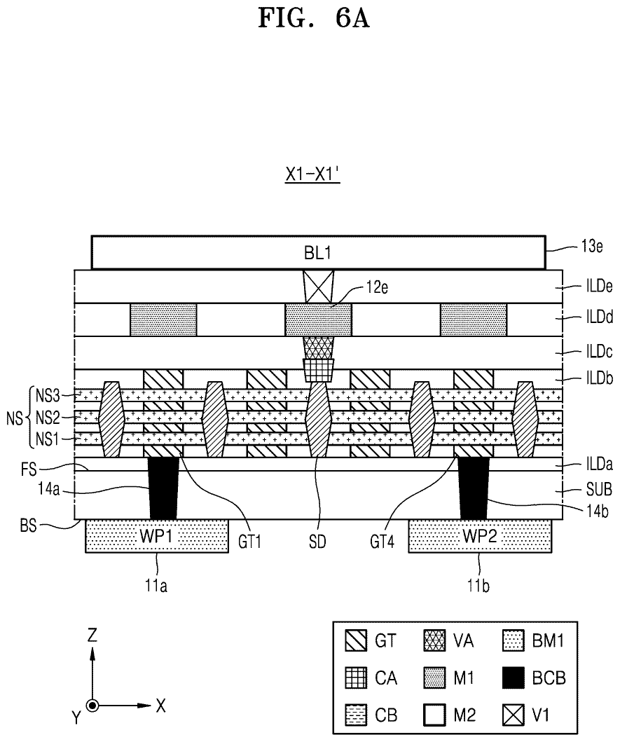

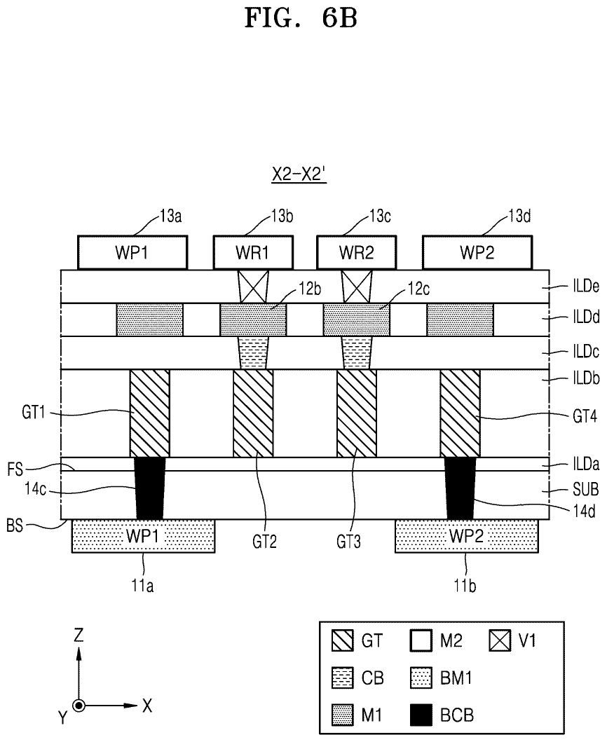

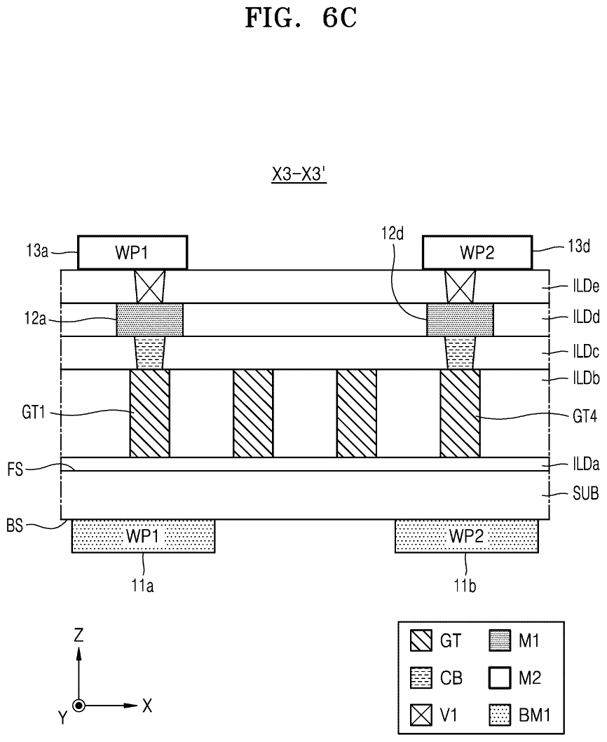

The integrated circuit 10 may be implemented as a semiconductor device, and a substrate including the semiconductor device formed thereon may include a first side (for example, a front side (FS) in FIG. 6A) and a second side (for example, a backside (BS) in FIG. 6A). A first side may be, for example, a side on which circuit devices such as transistors are arranged, and, as used herein, a first side may be referred to as a “front side”. A second side may be a side opposite to the first side, and, as used herein, the second side may be referred to as a “backside”.

The integrated circuit 10 may include the first and second front side wiring layers M1 and M2 and the backside wiring layer BM1, and by using the first and second front side wiring layers M1 and M2 and the backside wiring layer BM1, a power distribution network (PDN) may be implemented. In some implementations, the first and second front side wiring layers M1 and M2 may be arranged above a memory cell, for example, the OTP bit cell in the vertical direction Z, and the backside wiring layer BM may be arranged under the memory cell, for example, the OTP bit cell in the vertical direction Z.

As a result, some of signals and/or power applied to the integrated circuit 10 may be transferred via the first and second front side wiring layers M1 and M2, that is, via a front side PDN (FSPDN), and the remaining signals and/or power may be transferred via the backside wiring layer BM1, that is, via a backside PDN (BSPDN). Accordingly, according to some implementations, the routing complexity may be reduced compared to that of structures in which the wirings are arranged only on the front side of the substrate, and, because the length of each wiring or each via may be reduced, the performance of the integrated circuit 10 may be improved.

According to some implementations, the first and second front side wiring layers M1 and M2 may transfer, to the OTP bit cell, at least one of a program word line (for example, WLP in FIG. 5) signal, a read word line (for example, WLR in FIG. 5) signal, and a bit line (for example, BL in FIG. 5) signal. The backside wiring layer BM1 may transfer, to the OTP bit cell, at least one of the program word line WLP signal, a read word line WLR signal, and a bit line BL signal. In some implementations, the backside wiring layer BM1 may reduce a transfer path of a signal by transferring a signal to the OTP bit cell via first backside gate contacts 14a and 14b overlapping the active region RX, and accordingly, the performance of the integrated circuit 10 may be improved.

In some implementations, the backside wiring layer BM1 may transfer the program word line WLP signal to the OTP bit cell via the backside gate contacts BCB, and the first and second front side wiring layers M1 and M2 may transfer the program word line WLP signal and the read word line WLR signal to the OTP bit cell via the gate contacts CB and the second vias V1, and may transfer the bit line BL signal to the OTP bit cell via the first and second vias VA and V1.

The active region RX may extend in a first direction X. For example, the active region RX may be referred to as a diffusion region. The diffusion region may be a region doped with impurities that change electrical properties of a substrate material, and may form the source/drain regions of a transistor. The gate lines GT may each extend in a second direction Y, and may include gate lines GT1 through GT4 spaced apart from each other in the first direction X. The gate contacts CB may be arranged above the gate lines GT1 through GT4, respectively. The source/drain contacts CA may each extend in the active region RX in the second direction Y. The first via VA may be arranged on the source/drain contact CA between gate lines GT2 and GT3.

The first front side wiring layer M1 may be connected to the gate lines GT1 through GT4 via the gate contacts CB. For example, the first front side wiring layer M1 may include a front side wiring pattern 12a above the gate line GT1, a front side wiring pattern 12b above the gate line GT2, a front side wiring pattern 12c above the gate line GT3, a front side wiring pattern 12d above the gate line GT4. In addition, the first front side wiring layer M1 may be connected to the source/drain contact CA via the first via VA. For example, the first front side wiring layer M1 may further include a front side wiring pattern 12e between the gate lines GT2 and GT3. Widths and/or lengths of the front side wiring patterns 12a through 12e included in the first front side wiring layer M1 may be variously changed according to various implementations. In some implementations, a plurality of first front side wiring patterns spaced apart from each other may be arranged above the gate line GT1, and/or a plurality of front side wiring patterns spaced apart from each other may be arranged above the gate line GT4.

The second front side wiring layer M2 may include front side wiring lines 13a through 13e arranged above the first front side wiring layer M1. The second front side wiring layer M2 may be connected to the first front side wiring layer M1 via the second vias V1. For example, the second front side wiring layer M2 may include front side wiring lines 13a and 13a′ above the front side wiring pattern 12a, front side wiring lines 13b and 13b′ above the front side wiring pattern 12b, front side wiring lines 13c and 13c′ above the front side wiring pattern 12c, front side wiring lines 13d and 13d′ above the front side wiring pattern 12d, and a front side wiring line 13e above the front side wiring pattern 12e. Widths and/or lengths of the front side wiring lines 13a through 13e included in the second front side wiring layer M2 may be variously changed in various implementations.

The backside wiring layers BM1 may each extend in the second direction Y, and may include backside wiring lines 11a and 11b spaced apart from each other in the first direction X. The backside gate contacts BCB may be arranged on the backside wiring layer BM1, and may extend in the vertical direction Z. In some implementations, the backside gate contacts BCB may include first backside gate contacts 14a and 14b overlapping the active region RX. In some implementations, the backside gate contacts BCB may further include second backside gate contacts 14c through 14f that do not overlap the active region RX. In this manner or another manner, each of the backside wiring lines 11a and 11b may be connected to the gate lines GT1 and GT4 via a plurality of backside gate contacts 14a through 14f. As a result, resistance between the backside wiring lines 11a and 11b and the gate lines GT1 and GT4 may be reduced.

For example, a first backside gate contact 14a and second backside gate contacts 14c and 14e may be arranged on the backside wiring line 11a. The backside wiring line 11a may be connected to the gate line GT1 via the first backside gate contact 14a and the second backside gate contacts 14c and 14e. For example, the backside wiring line 11a may be connected to a gate of a program transistor included in a first OTP bit cell (for example, BC1 in FIG. 4), via the first backside gate contact 14a and the second backside gate contacts 14c and 14e.

For example, a first backside gate contact 14b and second backside gate contacts 14d and 14f may be arranged on the backside wiring line 11b. The backside wiring line 11b may be connected to the gate line GT4 via the first backside gate contact 14b and the second backside gate contacts 14d and 14f. For example, the backside wiring line 11b may be connected to a gate of a program transistor included in a second OTP bit cell (for example, BC2 in FIG. 4), via the first backside gate contact 14b and the second backside gate contacts 14d and 14f.

In this manner or another manner, the backside gate contacts BCB may connect layers and components on a backside of the substrate to components on the substrate, for example, gate lines. The backside gate contacts BCB may be respectively connected to the gate lines above the active region RX. According to some implementations, the backside gate contacts BCB may be referred to as “backside vias”. A structure in which a contact is connected to a lower portion of a gate line may be referred to as a “direct backside contract” (DBC). According to some implementations, the DBC may include a backside contact and/or a backside via.

According to some implementations, as shown in FIGS. 1 and 2A-2B, by using the backside wiring lines 11a and 11b included in the backside wiring layer BM1, the program word line WLP signal may be supplied to the OTP bit cell. In some implementations, because wiring widths of the backside wiring lines 11a and 11b may be arranged greater than wiring widths of the front side wiring lines, the wiring width of each of the backside wiring lines 11a and 11b may be increased, and thus, the program word line WLP signal may be smoothly supplied to the OTP bit cell.

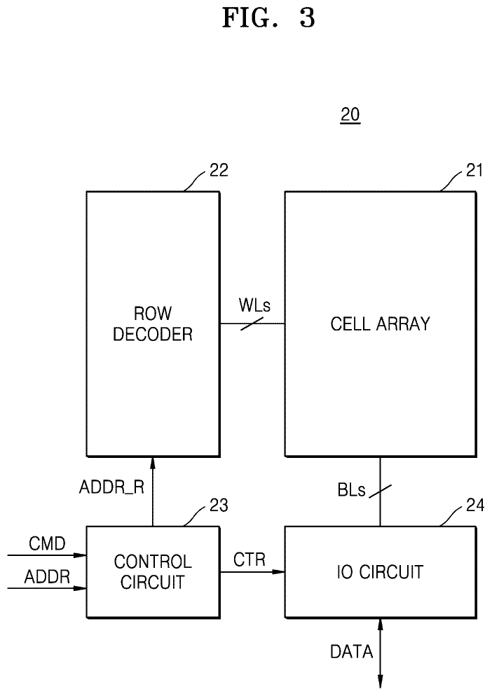

FIG. 3 is a block diagram of a memory device 20 included in an integrated circuit, according to some implementations.

Referring to FIG. 3, the memory device 20 may include a cell array 21, a row decoder 22, a control circuit 23, and an input/output (IO) circuit 24. The row decoder 22, the control circuit 23, and the IO circuit 24 may be comprehensively referred to as a periphery circuit. According to some implementations, the periphery circuit may further include a command buffer, an address buffer, and/or a voltage generator, etc. For example, the memory device 20 may be implemented as the integrated circuit 10 of FIG. 1.

The memory device 20 may receive a command CMD, an address ADDR, and data DATA. For example, the memory device 20 may receive the command CMD, the address ADDR, and data DATA, which indicates writing, and may store the received data DATA in a region of the cell array 21 corresponding to the address ADDR. In addition, the memory device 20 may receive the command CMD and the address ADDR, which directs reading, and may output data DATA stored in the region of the cell array 21 corresponding to the address ADDR to the outside.

The cell array 21 may include a plurality of bit cells BC or a plurality of memory cells, which are accessed by a plurality of word lines WLs and a plurality of bit lines BLs. In some implementations, the memory cells included in the cell array 21 may include the OTP bit cell BC. However, the scope of this disclosure is not limited thereto, and in some implementations, the memory cells included in the cell array 21 may include volatile memory cells, such as static random access memory (RAM) (SRAM) and dynamic RAM (DRAM). In some implementations, the memory cells included in the cell array 21 may also include non-volatile memory cells, such as flash memory and resistive RAM (RRAM). Some examples herein, e.g., as described below with reference to FIGS. 4 and 5, are described mainly with reference to the OTP bit cell, but the scope of this disclosure is not limited to OTP bit cells.

The control circuit 23 may generate a row address ADDR_R and a control signal CTR based on the command CMD and the address ADDR. For example, the control circuit 23 may identify a read command by decoding the command CMD, and may generate the row address ADDR_R and the control signal CTR to read data DATA from the cell array 21. In addition, the control circuit 23 may identify a write command by decoding the command CMD, and may generate the row address ADDR_R and the control signal CTR to write data DATA to the cell array 21.

The row decoder 22 may be connected to the cell array 21 via the plurality of word lines WLs, and may activate one of the plurality of word lines WLs according to the row address ADDR_R. Accordingly, memory cells connected to an activated word line may be selected from the memory cells included in the cell array 21. The row decoder 22 may include a row driver. In some implementations, it may be understood that the row decoder 22 includes a row driver.

The IO circuit 24 may be connected to the cell array 21 via the plurality of bit lines BLs, and may perform a read operation or a write operation according to the control signal CTR. For example, the IO circuit 24 may include a column driver. A column driver may sense a current and/or voltage from the plurality of bit lines BLs, or apply a current and/or voltage to the plurality of bit lines BLs, at a timing determined based on the control signal CTR.

FIG. 4 is a circuit diagram of an example of the cell array 21 according to some implementations.

Referring to FIG. 4, the cell array 21 may include first through fourth program word lines WLP1 through WLP4, first through fourth read word lines WLR1 through WLR4, and a plurality of OTP bit cells connected to first through fifth bit lines BL1 through BL5. For example, a first OTP bit cell BC1 may be connected to the first program word line WLP1, the first read word line WLR1, and the first bit line BL1. For example, the second OTP bit cell BC2 may be connected to the second program word line WLP2, the second read word line WLR2, and the first bit line BL1. In this manner or another manner, the first and second OTP bit cells BC1 and BC2 may be connected in common to the first bit line BL1.

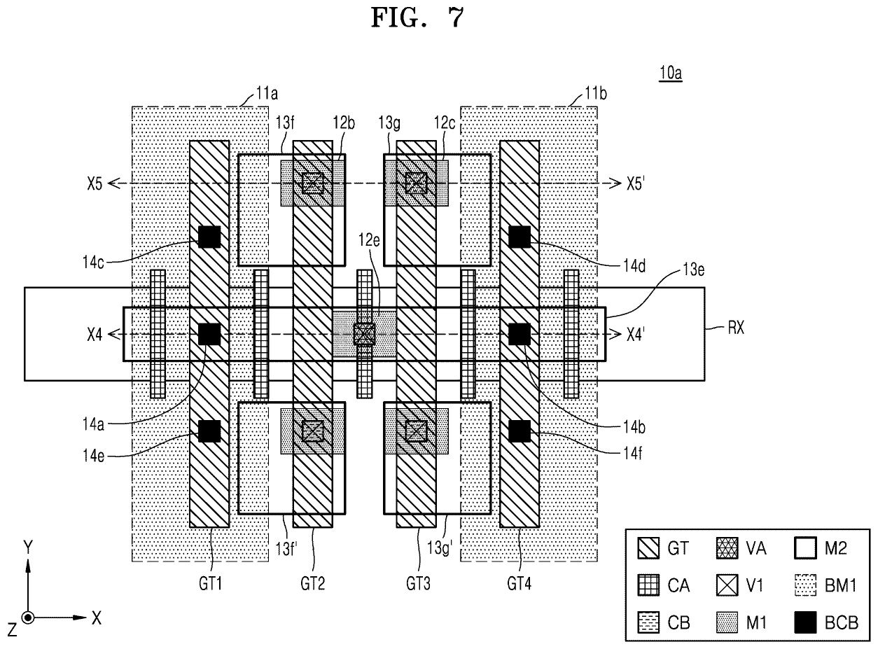

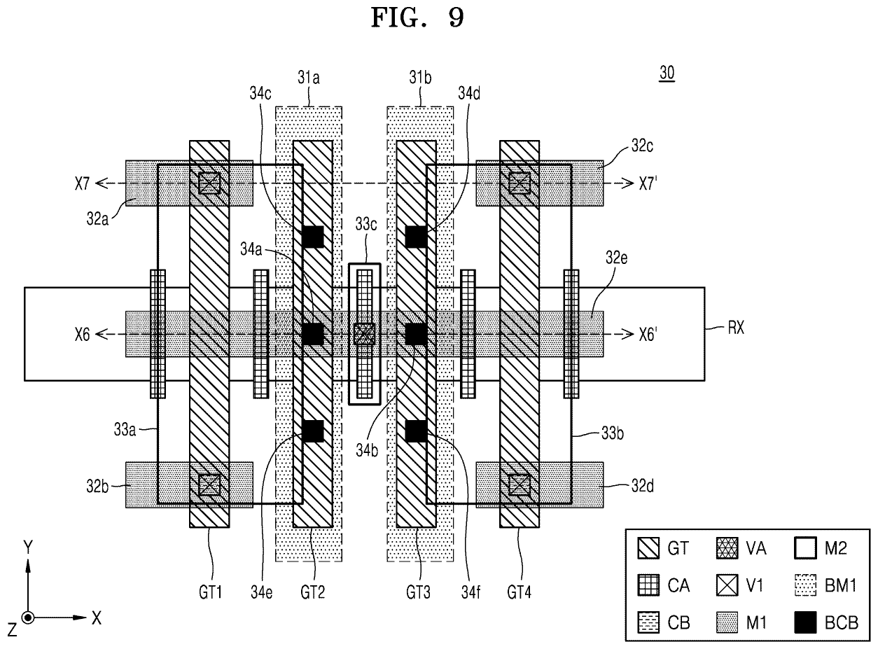

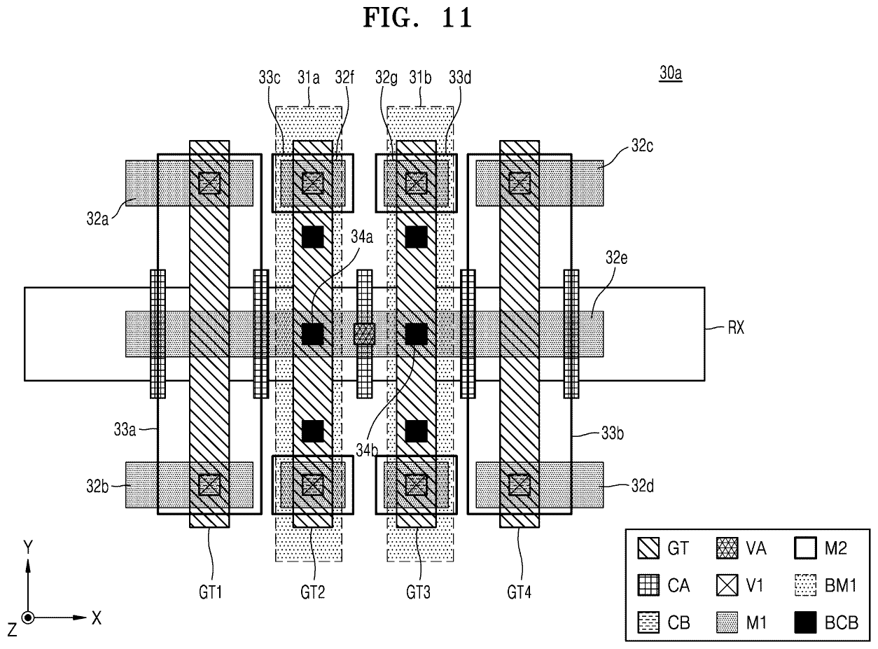

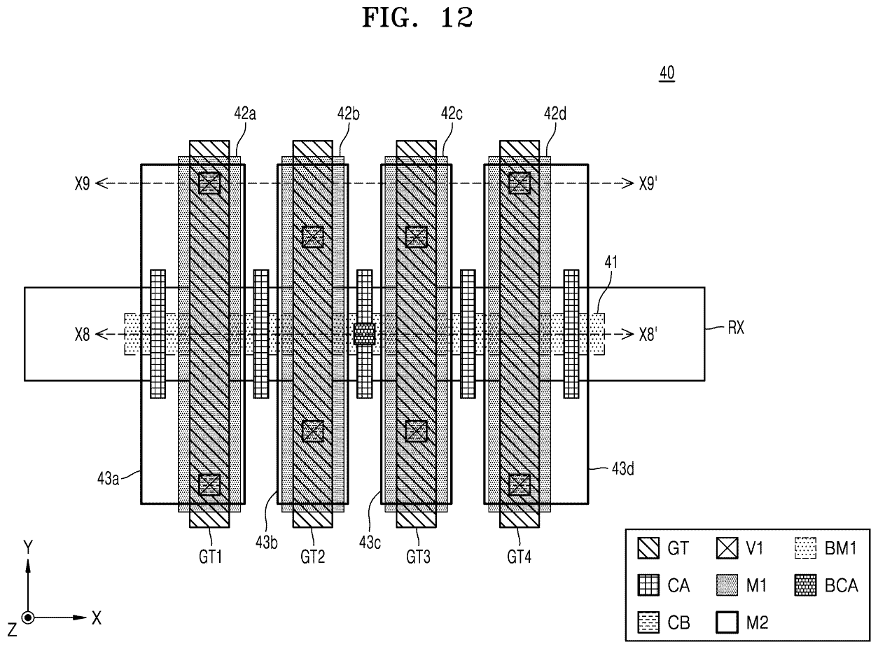

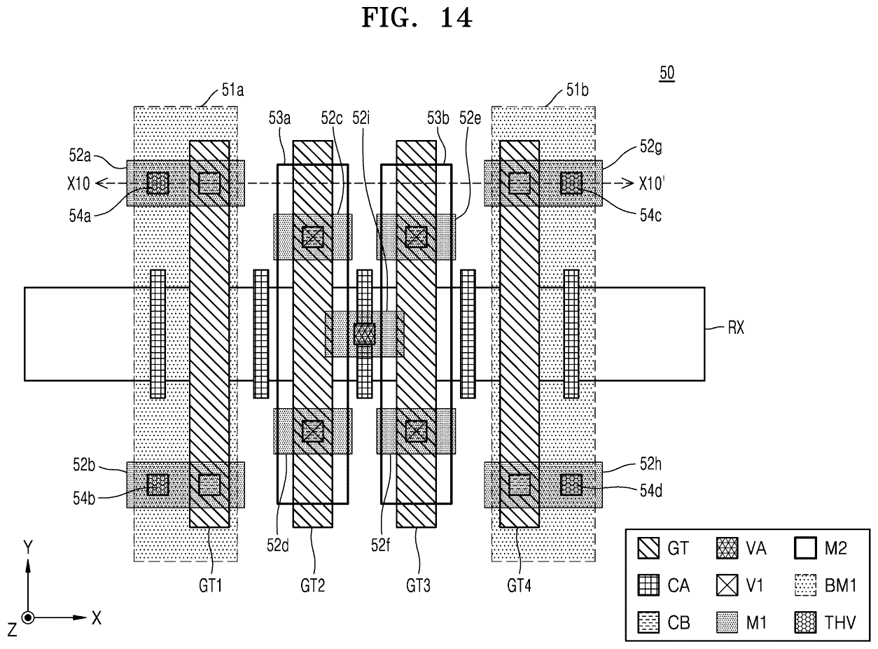

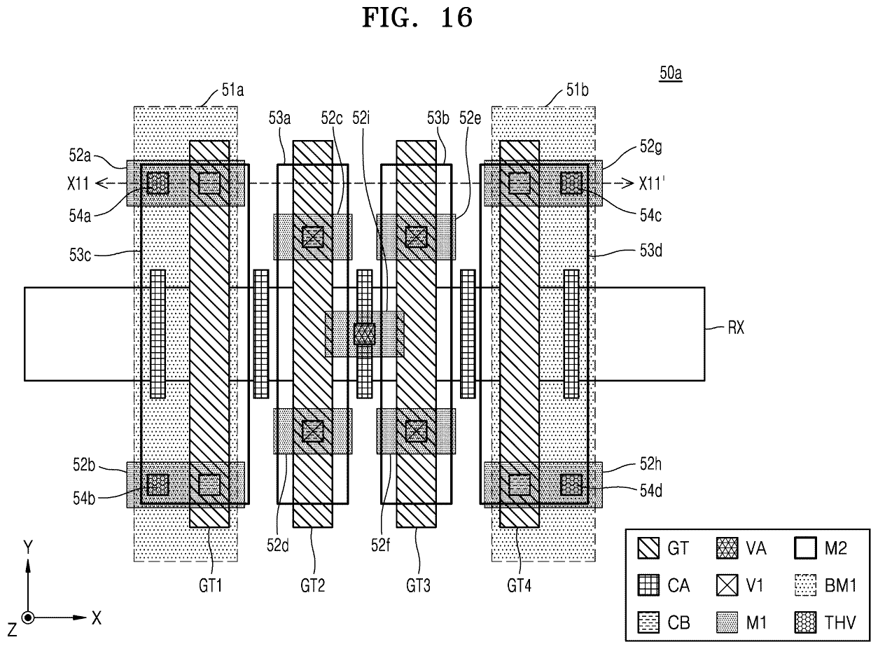

For example, the first and second OTP bit cells BC1 and BC2 may be arranged in the first region REG1. The integrated circuit 10 of FIG. 1, an integrated circuit 10a of FIG. 7, an integrated circuit 30 of FIG. 9, an integrated circuit 30a of FIG. 11, an integrated circuit 40 of FIG. 12, an integrated circuit 50 of FIG. 14, and an integrated circuit 50a of FIG. 16 may correspond to various examples of the first region REG1. In this manner, FIGS. 1 through 2B and 6 through 17 illustrate examples of the first and second OTP bit cells BC1 and BC2, but the descriptions corresponding thereto may also be applied to other OTP bit cells included in the cell array 21.

FIG. 5 is a circuit diagram of the OTP bit cell BC according to some implementations.

Referring to FIG. 5, the OTP bit cell BC may be included in, for example, the cell array 21 of FIG. 4. For example, the OTP bit cell BC may correspond to the first OTP bit cell BC1 or the second OTP bit cell BC2 in FIG. 4. The OTP bit cell BC may include a first transistor or a program transistor TO, and a second transistor or a read transistor T1. The program transistor TO may be a type of anti-fuse device, and may have a structure capable of changing a conduction state. The anti-fuse device may have a structure capable of changing from an un-conducted state to a conducted state, and may change a high resistance state to a low resistance state in response to electrical stress, such as a programming voltage and programming current. The programming voltage may be applied in a form of pulse of several to dozens of microseconds (μs). The anti-fuse device of this form may be implemented in a capacitor structure, or may be implemented in a transistor structure.

The program word line WLP may be connected to a gate of the program transistor TO. As illustrated in FIG. 5, a source and a drain of the program transistor TO may be connected to each other. However, the scope of this disclosure is not limited thereto, and the source of the program transistor TO may be connected to a drain of the read transistor T1 and the drain of the program transistor TO may be floating, or another connection configuration may be used.

The read word line WLR may be connected to a gate of the read transistor T1, one of the source/drain of the read transistor T1 may be connected to the source/drain of the program transistor TO, and the other of the source/drain of the read transistor T1 may be connected to the bit line BL. The read transistor T1 may perform a switching function, and when an operating voltage is applied to the gate of the read transistor T1 via the read word line WLR, the read transistor T1 may be turned on.

Before a program voltage is applied to the gate of the program transistor TO, a high resistance state may be maintained between the gate and the source of the program transistor TO by a gate oxide layer. Accordingly, even when a certain voltage is applied to the gate of the program transistor TO and the bit line BL, and an operating voltage is applied to the gate of the read transistor T1, a current flowing through the bit line BL may be relatively small.

When a high voltage, that is, a program voltage is applied to the gate of the program transistor TO via the program word line WLP, a gate oxide layer may be broken, and a current path between the gate and the source may be formed. Accordingly, a high resistance state between a gate and a source may be transitioned to a low resistance state. In this manner or another manner, when the program transistor TO enters a low resistance state, a certain voltage is applied to the gate of the program transistor TO and the bit line BL, and an operating voltage is applied to the gate of the read transistor T1, the current flowing through the bit line BL may be relatively large. In this manner or another manner, the OTP bit cell BC may store data DATA by receiving the program voltage of a high voltage.

In some cases, for a smooth program operation on the OTP bit cell BC, it may be important that the program word line WLP signal is transferred to the gate of the program transistor TO without a loss. To this end, when a layout of an integrated circuit including the OTP bit cell BC is designed, it may be desirable to reduce parasitic resistance of the program word line WLP. In addition, for a smooth read operation for the OTP bit cell BC, it may be important that the read word line WLR signal is transferred to the gate of the read transistor T1 without a loss. To this end, when a layout of an integrated circuit including the OTP bit cell BC is designed, it may be desirable to reduce parasitic resistance of the read word line WLR. Furthermore, for a smooth read operation on the OTP bit cell BC, it may also be important to reduce the parasitic resistance of the bit line BL. Some implementations of the present disclosure described herein illustrate various routing methods for lowering the IR drop of the program word line WLP signal, the read word line WLR signal, and/or the bit line BL signal, by reducing parasitic resistances of the program word line WLP, the read word line WLR, and/or the bit line BL signal with respect to the OTP bit cell BC.

FIG. 6A is a cross-sectional view of the integrated circuit 10 of FIG. 1 taken along line X1 -X1′ in FIG. 1, according to some implementations, FIG. 6B is a cross-sectional view of the integrated circuit 10 of FIG. 1 taken along line X2-X2′ in FIG. 1, according to some implementations, and FIG. 6C is a cross-sectional view of the integrated circuit 10 of FIG. 1 taken along line X3-X3′ in FIG. 1, according to some implementations.

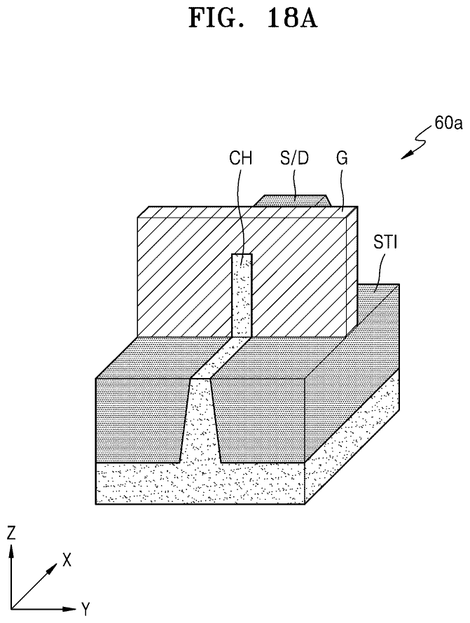

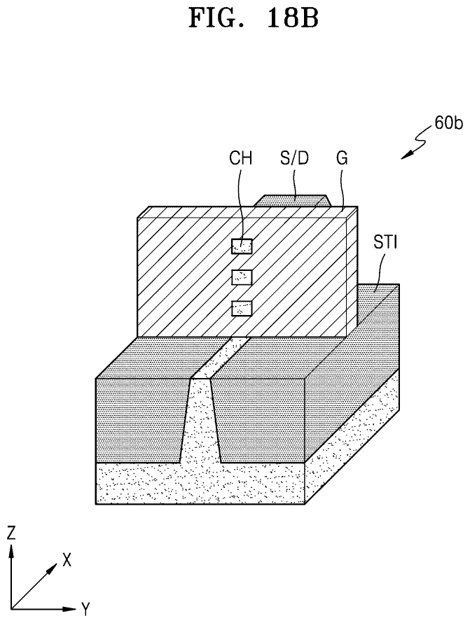

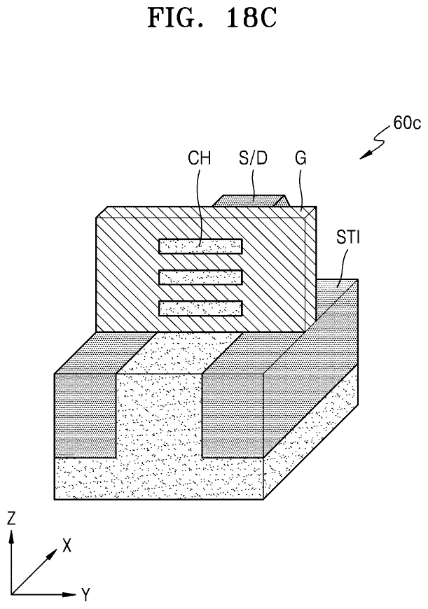

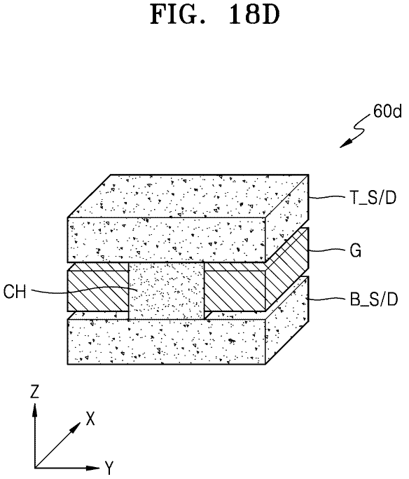

FIG. 6A illustrates an example of a nanosheet formed on an active region. For example, in the active region, a multi bridge channel (MBC) FET, in which a plurality of nanosheets are stacked in the active region and the gate line surrounds the plurality of nanosheets, may be formed. However, the integrated circuit is not limited to the configuration illustrated in FIG. 6A. For example, a fin field effect transistor (FinFET) including a fin and a gate line formed on the active region may be included. As another example, a gate-all-around (GAA) FET may be included, in which nanowires formed on the active region are surrounded by gate lines. As another example, a vertical GAA FET may be included, in which a plurality of nanowires are vertically stacked on the active region and a plurality of nanowires are surrounded by a gate line. Examples of various device types are described in more detail with reference to FIGS. 18A through 18D.

Referring to FIGS. 1 and 6A together, a substrate SUB may include a semiconductor substrate including a front side FS and a backside BS. For example, a semiconductor substrate may include any one of silicon, silicon-on-insulator, silicon-on-sapphire, germanium, silicon-germanium, and gallium arsenide. For example, an upper region of the substrate SUB may correspond to the active region RX. Interlayer insulating layers ILDa through ILDe may be arranged above the substrate SUB. The interlayer insulating layers ILDa through ILDe may include an insulating material, and the insulating material may include any one, for example, of an oxide layer, a nitride layer, and an oxynitride layer.

In some implementations, the substrate SUB may correspond to a bulkless substrate. In the manufacturing process of the integrated circuit 10, a device wafer may be formed by forming the gate lines, the source/drain regions, the contacts, the vias, and/or the wiring layers on the front side of the substrate SUB. Next, the device wafer may be temporarily bonded to a carrier wafer, and at least a portion of the substrate SUB may be removed by performing a back-grinding process on the device wafer. In this manner, a wafer, which is back-ground so that a height of the substrate SUB is equal to or less than a reference height, may be referred to as a “bulkless wafer” or a “bulkless substrate”.

A nanosheet stack NS extending in the first direction X may be arranged above the front side FS of the substrate SUB. The nanosheet stack NS may include a plurality of nanosheets overlapping each other in the vertical direction Z, for example, first through third nanosheets NS1 through NS3. For example, the nanosheet stack NS may be doped with P-type impurities, and may form a P-type transistor. As another example, the nanosheet stack NS may be doped with N-type impurities, and may form an N-type transistor. In some implementations, the nanosheet stack NS may include Si, Ge, or SiGe. In some implementations, the nanosheet stack NS may include InGaAs, InAs, GaSb, InSb, or a combination thereof.

The gate lines GT may respectively surround the first through third nanosheets NS1 through NS3 while covering the nanosheet stack NS. As a result, the first through third nanosheets NS1 through NS3 may have a GAA structure. The gate lines GT may be defined as conductive segments including a conductive material, such as polysilicon and/or one or more metals. A gate insulating layer may be arranged between each of the gate lines GT and each of the first through third nanosheets NS1 through NS3. A source/drain region SD may include an epitaxial region of a semiconductor material, such as silicon, boron, germanium, carbon, SiGe, and/or SiC.

The backside wiring lines 11a and 11b may be arranged on the backside BS of the substrate SUB. The backside wiring lines 11a and 11b may each extend in the second direction Y, and may be spaced apart from each other in the first direction X. For example, the backside wiring line 11a may receive a first program word line signal WP1, and the backside wiring line 11b may receive a second program word line signal WP2. The backside wiring lines 11a and 11b may be arranged on the same level. An upper surface level of each of the backside wiring lines 11a and 11b may be the same. In addition, or alternatively, a lower surface level of each of the backside wiring lines 11a and 11b may be the same.

However, the scope of this disclosure is not limited thereto, and according to some implementations, the backside wiring lines 11a and 11b may be arranged on different levels from each other. A lower surface of one among the backside wiring lines 11a and 11b may be different from an upper surface level of the other among the backside wiring lines 11a and 11b. For example, the lower level of one of the backside wiring lines 11a and 11b may be above the upper level of the other of the backside wiring lines 11a and 11b in the vertical direction Z. The backside wiring lines 11a and 11b may be electrically insulated from each other.

Backside gate contacts 14a and 14b may be arranged on the backside wiring lines 11a and 11b, respectively, and may penetrate the substrate SUB and extend in the vertical direction Z. The backside gate contact 14a may electrically connect the backside wiring line 11a to the gate line GT1, and the backside gate contact 14b may electrically connect the backside wiring line 11b to the gate line GT4. In some implementations, a backside via may be further arranged between the backside wiring line 11a and the backside gate contact 14a, and the backside via may be further arranged between the backside wiring line 11b and the backside gate contact 14b. In some implementations, a via or a backside via may be further arranged between the backside gate contact 14a and the gate line GT1, and a via or a backside via may be further arranged between the backside gate contact 14b and the gate line GT4.

According to some implementations, a first OTP bit cell BC1 may receive the first program word line signal WP1 from the backside wiring line 11a via the backside gate contact 14a overlapping the active region RX, and a second OTP bit cell BC2 may receive the second program word line signal WP2 from the backside wiring line 11b via the backside gate contact 14b overlapping the active region RX. For example, the first and second OTP bit cells BC1 and BC2 may receive the first and second program word line signals WP1 and WP2 via the DBC structure. Accordingly, by reducing routing resistance of the first and second program word line signals WP1 and WP2, the IR drop of the first and second program word line signals WP1 and WP2 may be reduced, and as a result, the performance of the integrated circuit 10 may be improved.

The source/drain region SD may be connected to the front side wiring pattern 12e via the source/drain contact CA and the first via VA. The front side wiring pattern 12e may be connected to the front side wiring line 13e via a second via V1. The front side wiring line 13e may correspond to the first bit line BL1, and may receive a first bit line BL1 signal. As a result, the source/drain region SD may receive the first bit line BL1 signal via the first and second front side wiring layers M1 and M2. For example, the source/drain region SD may correspond to a drain of a read transistor of the first OTP bit cell (BC1 in FIG. 4) and a drain of the second OTP bit cell (BC2 in FIG. 4). In this manner or another manner, the first and second OTP bit cells BC1 and BC2 may share the source/drain region SD.

Referring to FIG. 6B, the gate line GT2 may be connected to a front side wiring pattern 12b via the gate contact CB, and the front side wiring pattern 12b may be connected to a front side wiring line 13b via the second via V1. The gate line GT3 may be connected to the front side wiring pattern 12c via the gate contact CB, and the front side wiring pattern 12c may be connected to the front side wiring line 13c via the second via V1. The front side wiring line 13b may receive a first read word line signal WR1, and the front side wiring line 13c may receive a second read wiring line signal WR2. As a result, the gate lines GT2 and GT3 may receive the first and second read word line signals WR1 and WR2 via the first and second front side wiring layers M1 and M2, respectively.

Referring to FIG. 6C, the gate line GT1 may be connected to the front side wiring pattern 12a via the gate contact CB, and the front side wiring pattern 12a may be connected to the front side wiring line 13a via the second via V1. The gate line GT4 may be connected to the front side wiring pattern 12d via the gate contact CB, and the front side wiring pattern 12d may be connected to the front side wiring line 13d via the second via V1. The front side wiring line 13a may receive a first program word line signal WP1, and the front side wiring line 13d may receive the second program word line signal WP2. As a result, the gate lines GT1 and GT4 may receive the first and second program word line signals WP1 and WP2 via the first and second front side wiring layers M1 and M2, respectively.

According to some implementations, the first OTP bit cell BC1 may receive the first program word line signal WP1 from the backside wiring line 11a, the front side wiring line 13a, and the front side wiring pattern 12a, and the second OTP bit cell BC2 may receive the second program word line signal WP2 from the backside wiring line 11b, the front side wiring line 13d, and the front side wiring pattern 12d. In this manner or another manner, by using the first and second front side wiring layers M1 and M2 and the backside wiring layer BM1 for the first and second OTP bit cells BC1 and BC2, the first and second program word line signals WP1 and WP2 may be supplied. Thus, the IR drop of the first and second program word line signals WP1 and WP2 may be further reduced, and as a result, the performance of the integrated circuit 10 may be further improved.

FIG. 7 illustrates a layout of the integrated circuit 10a according to some implementations.

Referring to FIG. 7, the integrated circuit 10a may correspond to a modified example of the integrated circuit 10 of FIG. 1, and hereinafter, differences between the integrated circuit 10a and the integrated circuit 10 of FIG. 1 are described; other characteristics can be the same except where noted otherwise. The integrated circuit 10a may include the active region RX, the gate lines GT, the source/drain contacts CA, the gate contacts CB, the first via VA, the second vias V1, the first front side wiring layer M1, the second front side wiring layer M2, the backside wiring layer BM1, and the backside gate contacts BCB.

In some implementations, the backside wiring layer BM1 may transfer the program word line WLP signal to the OTP bit cell via the backside gate contacts BCB, and the first and second front side wiring layers M1 and M2 may transfer the read word line WLR signal to the OTP bit cell via the gate contacts CB and the second vias V1, and may transfer the bit line BL signal to the OTP bit cell via the first and second vias VA and V1.

Hereinafter, components of the integrated circuit 10a are described in detail.

The first front side wiring layer M1 may include the first wiring patterns 12b, 12c, and 12e arranged above the upper portions of the gate lines GT1 through GT4. The first front side wiring layer M1 may be connected to the gate lines GT2 and GT3 via the gate contacts CB. For example, the first front side wiring layer M1 may include the front side wiring patterns 12b above the gate line GT2, and the front side wiring patterns 12c above the gate line GT3. In addition, the first front side wiring layer M1 may be connected to the source/drain contact CA via the first via VA. For example, the first front side wiring layer M1 may further include the front side wiring pattern 12e between the gate lines GT2 and GT3. In this manner or another manner, according to some implementations, unlike the example illustrated in FIG. 1, front side wiring patterns of the first front side wiring layer M1 may not be arranged above the gate lines GT1 and GT4, e.g., may be spaced apart from the gate lines GT1 and GT4 in the first direction X and/or the second direction Y.

The second front side wiring layer M2 may include front side wiring lines 13e, 13f, 13f, 13g, and 13g′ arranged above the first front side wiring layer M1. The second front side wiring layer M2 may be connected to the first front side wiring layer M1 via the second vias V1. For example, the second front side wiring layer M2 may include the front side wiring line 13e above the front side wiring pattern 12e, the front side wiring lines 13f and 13f′ above the front side wiring pattern 12b, and front side wiring lines 13g and 13g′ above the front side wiring patterns 12c. In this manner or another manner, according to some implementations, unlike the example illustrated in FIG. 1, the front side wiring lines 13f, 13f′, 13g, and 13g′ of the second front side wiring layer M2 may not be arranged above the gate lines GT1 and GT4, e.g., may be spaced apart from the gate lines GT1 and GT4 in the first direction X and/or the second direction Y.

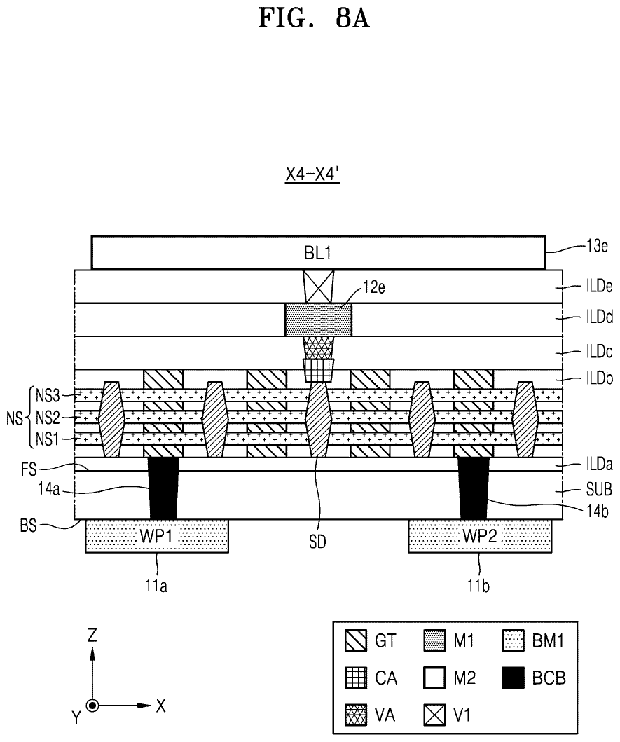

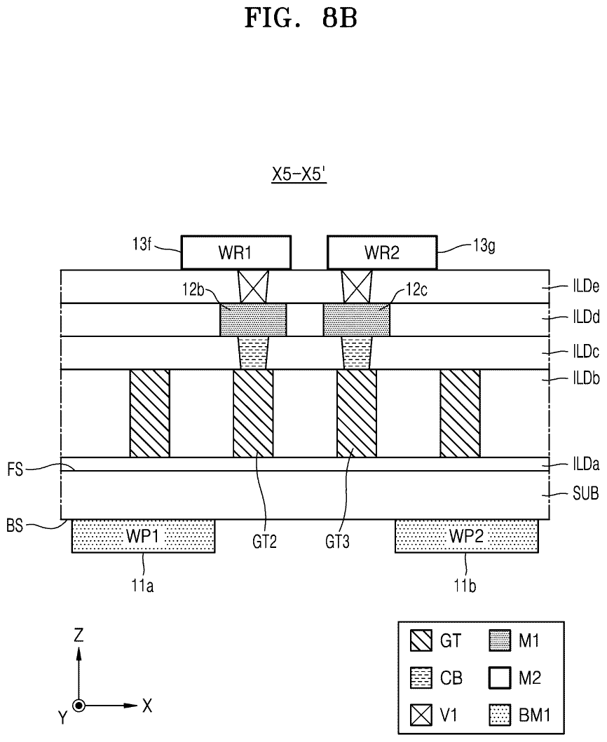

FIG. 8A is a cross-sectional view of the integrated circuit 10a of FIG. 7 taken along line X4-X4′ in FIG. 7, according to some implementations, and FIG. 8B is a cross-sectional view of the integrated circuit 10a of FIG. 7 taken along line X5-X5′ in FIG. 7, according to some implementations. Descriptions given with reference to FIGS. 6A through 6C may also be applied to the integrated circuit 10a.

Referring to FIG. 8A, the backside wiring lines 11a and 11b may be arranged on the backside BS of the substrate SUB. For example, the backside wiring line 11a may receive a first program word line signal WP1, and the backside wiring line 11b may receive a second program word line signal WP2. The source/drain region SD may be connected to the front side wiring pattern 12e via the source/drain contact CA and the first via VA. The front side wiring pattern 12e may be connected to the front side wiring line 13e via a second via V1. The front side wiring line 13e may correspond to the first bit line BL1, and may receive a first bit line BL1 signal.

Referring to FIG. 8B, the gate line GT2 may be connected to a front side wiring pattern 12b via the gate contact CB, and the front side wiring pattern 12b may be connected to the front side wiring line 13f via the second via V1. The gate line GT3 may be connected to the front side wiring pattern 12c via the gate contact CB, and the front side wiring pattern 12c may be connected to the front side wiring line 13g via the second via V1. The front side wiring line 13f may receive the first read word line signal WR1, the front side wiring line 13g may receive the second read wiring line signal WR2, and in this manner or another manner, the gate lines GT2 and GT3 may receive the first and second word line signals WR1 and WR2 via the first and second front side wiring layers M1 and M2, respectively.

According to some implementations, the first and second OTP bit cells BC1 and BC2 may receive the first and second program word line signals WP1 and WP2 via the DBC structure. Accordingly, the IR drop of the first and second program word line signals WP1 and WP2 may be reduced, and as a result, the performance of the integrated circuit 10a may be improved. In addition, according to some implementations, by arranging the program word line signal wiring in the backside wiring layer BM1 (e.g., as opposed to in the front side wiring layer), the wiring width of the front side wiring line included in the front side wiring layer may be increased. For example, the wiring width of each of the read word line signal wiring, that is, the front side wiring lines 13f, 13f, 13g, and 13g′ included in the second front side wiring layer M2 may be increased. Thus, parasitic resistance with respect to the read word line WLR may be reduced, and as a result, the read word line WLR signal may be smoothly supplied to the OTP bit cell, and the performance of the integrated circuit 10a may be further improved.

FIG. 9 illustrates a layout of an integrated circuit 30 according to some implementations.

Referring to FIG. 9, the integrated circuit 30 may include the active region RX, the gate lines GT, the source/drain contacts CA, the gate contacts CB, the first via VA, the second vias V1, the first front side wiring layer M1, the second front side wiring layer M2, the backside wiring layer BM1, and the backside gate contacts BCB. The integrated circuit 30 according to some implementations may correspond to a modified example of the integrated circuit 10 of FIG. 1, and the descriptions given with reference to FIGS. 1 through 6C may also be applied to the integrated circuit 30 and its elements.

In some implementations, the backside wiring layer BM1 may transfer the read word line WLR signal to the OTP bit cell via the backside gate contacts BCB, and the first and second front side wiring layers M1 and M2 may transfer the program word line WLP signal to the OTP bit cell via the gate contacts CB and the second vias V1, and may transfer the bit line BL signal to the OTP bit cell via the first and second vias VA and V1.

The gate contacts CB may be arranged on each of the gate lines GT1 and GT4. The first front side wiring layer M1 may include the front side wiring patterns 32a through 32e arranged above the gate lines GT1 and GT4. The first front side wiring layer M1 may be connected to the gate lines GT1 and GT4 via the gate contacts CB. For example, the first front side wiring layer M1 may include the front side wiring patterns 32a and 32b above the gate line GT1, and the front side wiring patterns 32c and 32d above the gate line GT4. In addition, the first front side wiring layer M1 may be connected to the source/drain contact CA via the first via VA. For example, the first front side wiring layer M1 may further include a front side wiring pattern 32e on the first via VA. Widths and/or lengths of the front side wiring patterns 32a through 32e included in the first front side wiring layer M1 may vary according to different implementations.

The second front side wiring layer M2 may include front side wiring lines 33a, 33b, and 33c arranged above the first front side wiring layer M1. The second front side wiring layer M2 may be connected to the first front side wiring layer M1 via the second vias V1. For example, the second front side wiring layer M2 may include the front side wiring line 33a above the front side wiring patterns 32a and 32b, the front side wiring line 33b above the front side wiring patterns 32c and 32d, and the front side wiring line 33c above the front side wiring pattern 32e. Widths and/or lengths of the front side wiring lines 33a, 33b, and 33c included in the second front side wiring layer M2 may vary according to different implementations.

The backside wiring layers BM1 may include backside wiring lines 31a and 31b spaced apart from each other in the first direction X and each extending in the second direction Y. The backside gate contacts BCB may be arranged on the backside wiring layer BM1, and may extend in the vertical direction Z. In some implementations, the backside gate contacts BCB may include first backside gate contacts 34a and 34b overlapping the active region RX. In addition, in some implementations, the backside gate contacts BCB may further include second backside gate contacts 34c through 34f that do not overlap the active region RX.

For example, the first backside gate contact 34a and the second backside gate contacts 34c and 34e may be arranged on the backside wiring line 31a. The backside wiring line 31a may be connected to the gate line GT2 via the first backside gate contact 34a and the second backside gate contacts 34c and 34e. For example, the backside wiring line 31a may be connected to a gate of a read transistor included in the first OTP bit cell (for example, BC1 in FIG. 4), via the first backside gate contact 34a and the second backside gate contacts 34c and 34e.

For example, the first backside gate contact 34b and the second backside gate contacts 34d and 34f may be arranged on the backside wiring line 31b. The backside wiring line 31b may be connected to the gate line GT3 via the first backside gate contact 34b and the second backside gate contacts 34d and 34f. For example, the backside wiring line 31b may be connected to a gate of a read transistor included in the second OTP bit cell (for example, BC2 in FIG. 4), via the first backside gate contact 34b and the second backside gate contacts 34d and 34f.

According to some implementations, by using the backside wiring lines 31a and 31b included in the backside wiring layer BM1, the read word line WLR signal may be supplied to the OTP bit cell. In such cases, because the wiring width of the backside wiring lines 31a and 31b may be greater than the wiring width of the front side wiring lines, the wiring width of each of the backside wiring lines 31a and 31b may be increased. Accordingly, parasitic resistance with respect to the read word line WLR may be reduced, and as a result, the read word line WLR signal may be smoothly supplied to the OTP bit cell BC, and the performance of the integrated circuit 30 may be further improved.

In addition, according to some implementations, by supplying the read word line WLR signal to the OTP bit cell BC by using the backside wiring lines 31a and 31b, because the read word line WLR may be removed from the first and second front side wiring layers M1 and M2, the wiring width of each of the front side wiring lines 33a and 33b may be increased. For example, the wiring width of the front side wiring line 33a may be increased to an upper area of the gate line GT2, and in addition, the wiring width of the front side wiring line 33b may be increased to an upper area of the gate line GT3. Thus, because the resistance with respect to the first and second program word line signals WP1 and WP2, which are respectively received through the front side wiring lines 33a and 33b, may be reduced, the IR drop of the first and second program word line signals WP1 and WP2 may be reduced.

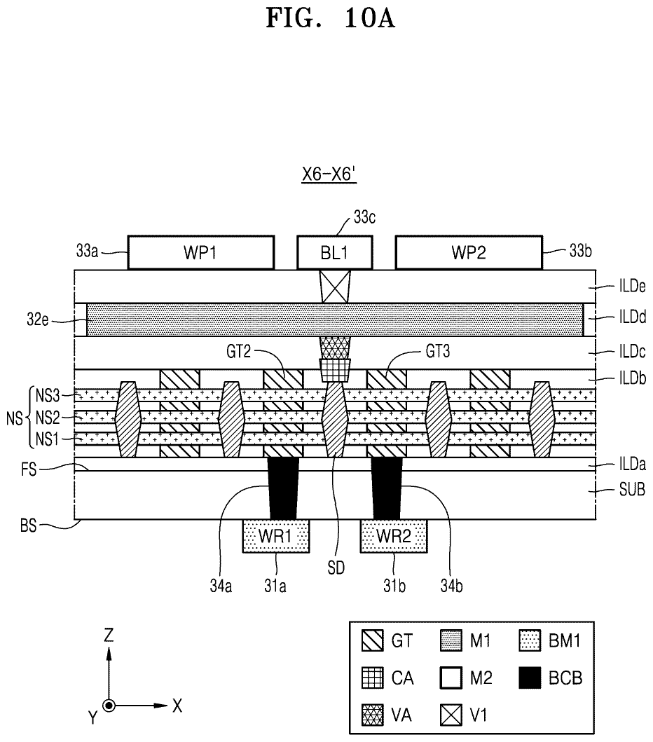

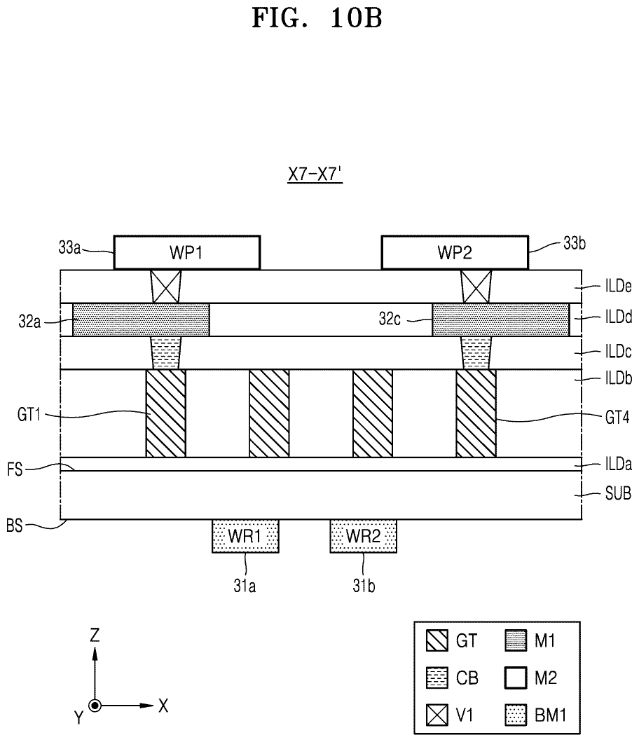

FIG. 10A is a cross-sectional view of the integrated circuit 30 of FIG. 9 taken along line X6-X6′ in FIG. 9, according to some implementations, and FIG. 10B is a cross-sectional view of the integrated circuit 30 of FIG. 9 taken along line X7-X7′ in FIG. 9, according to some implementations. Descriptions given with reference to FIGS. 6A through 6C may also be applied to the integrated circuit 30.

Referring to FIG. 10A, the backside wiring lines 31a and 31b may be arranged on the backside BS of the substrate SUB. The backside wiring lines 31a and 31b may each extend in the second direction Y, and may be spaced apart from each other in the first direction X. For example, the backside wiring line 31a may receive the first read word line signal WR1, and the backside wiring line 31b may receive the second read word line signal WR2. Backside gate contacts 34a and 34b may be arranged on the backside wiring lines 31a and 31b, respectively, and may penetrate the substrate SUB and extend in the vertical direction Z. The backside gate contact 34a may electrically connect the backside wiring line 31a to the gate line GT2, and the backside gate contact 34b may electrically connect the backside wiring line 31b to the gate line GT3.

According to some implementations, the first OTP bit cell BC1 may receive the first read word line signal WR1 from the backside wiring line 31a via the backside gate contact 34a overlapping the active region RX, and the second OTP bit cell BC2 may receive the second read word line signal WR2 from the backside wiring line 31b via the backside gate contact 34b overlapping the active region RX. For example, the first and second OTP bit cells BC1 and BC2 may be receive the first and second read word line signals WR1 and WR2 via the DBC structure. Accordingly, by reducing routing resistance of the first and second read word line signals WR1 and WR2, the IR drop of the first and second read word line signals WR1 and WR2 may be reduced, and as a result, the performance of the integrated circuit 30 may be improved.

The source/drain region SD may be connected to the front side wiring pattern 32e via the source/drain contact CA and the first via VA. The front side wiring pattern 32e may be connected to the front side wiring line 33c via the second via V1. The front side wiring line 33c may correspond to the first bit line BL1, and may receive a first bit line BL1 signal. As a result, the source/drain region SD may receive the first bit line BL1 signal via the first and second front side wiring layers M1 and M2. For example, the source/drain region SD may correspond to a drain of a read transistor of the first OTP bit cell (e.g., BC1 in FIG. 4) and a drain of the second OTP bit cell (e.g., BC2 in FIG. 4). Accordingly, the first and second OTP bit cells BC1 and BC2 may share the source/drain region SD.

Referring to FIG. 10B, the gate line GT1 may be connected to the front side wiring pattern 32a via the gate contact CB, and the front side wiring pattern 32a may be connected to the front side wiring line 33a via the second via V1. The gate line GT4 may be connected to the front side wiring pattern 32c via the gate contact CB, and the front side wiring pattern 32c may be connected to the front side wiring line 33b via the second via V1. The front side wiring line 33a may receive the first program word line signal WP1, the front side wiring line 33b may receive the second program word line signal WP2, and in this manner or another manner, the gate lines GT1 and GT4 may receive the first and second program word line signals WP1 and WP2 via the first and second front side wiring layers M1 and M2, respectively.

FIG. 11 illustrates a layout of the integrated circuit 30a according to some implementations.

Referring to FIG. 11, the integrated circuit 30a may correspond to a modified example of the integrated circuit 30 of FIG. 9, and hereinafter, differences between the integrated circuit 30a according to some implementations and the integrated circuit 30 of FIG. 9 are described. The integrated circuit 30a may include the active region RX, the gate lines GT, the source/drain contacts CA, the gate contacts CB, the first via VA, the second vias V1, the first front side wiring layer M1, the second front side wiring layer M2, the backside wiring layer BM1, and the backside gate contacts BCB.

In some implementations, the backside wiring layer BM1 may transfer the program word line WLP signal to the OTP bit cell via the backside gate contacts BCB, and the first and second front side wiring layers M1 and M2 may transfer the program word line WLP signal and the read word line WLR signal to the OTP bit cell via the gate contacts CB and the second vias V1, and may transfer the bit line BL signal to the OTP bit cell via the first and second vias VA and V1.

The first front side wiring layer M1 may include a plurality of front side wiring patterns 32a through 32g extending in the first direction X above the gate lines GT1 through GT4. The first front side wiring layer M1 may be connected to the gate lines GT1 through GT4 via the gate contacts CB. For example, the first front side wiring layer M1 may include the front side wiring patterns 32a and 32b above the gate line GT1, the front side wiring patterns 32f above the gate line GT2, the front side wiring patterns 32g above the gate line GT3, the front side wiring pattern 32c and 32d above the gate line GT4. In this manner or another manner, according to some implementations, unlike some implementations of the configuration illustrated in FIG. 9, the front side wiring patterns of the first front side wiring layer M1 may be arranged above the gate lines GT2 and GT3.

The second front side wiring layer M2 may include the plurality of front side wiring lines 33a through 33d arranged above the first front side wiring layer M1. The second front side wiring layer M2 may be connected to the first front side wiring layer M1 via the second vias V1. For example, the second front side wiring layer M2 may include the front side wiring line 33a above the front side wiring patterns 32a and 32b, the front side wiring line 33b above the front side wiring patterns 32c and 32d, the front side wiring line 33c above the front side wiring pattern 32f, and the front side wiring line 33d above the front side wiring pattern 32g. In this manner or another manner, according to some implementations, unlike some implementations of the configuration illustrated in FIG. 9, the front side wiring lines of the second front side wiring layer M2 may be arranged above the gate lines GT2 and GT3.

According to some implementations, the first OTP bit cell BC1 may receive the first read word line signal WR1 from the backside wiring line 31a, the front side wiring line 33c, and the front side wiring pattern 32f, and the second OTP bit cell BC2 may receive the second read word line signal WR2 from the backside wiring line 31b, the front side wiring line 33d, and the front side wiring pattern 32g. In this manner or another manner, by using the first and second front side wiring layers M1 and M2 and the backside wiring layer BM1 for the first and second OTP bit cells BC1 and BC2, the first and second read word line signals WR1 and WR2 may be supplied. Thus, the IR drop of the first and second read word line signals WR1 and WR2 may be further reduced, and as a result, the performance of the integrated circuit 30a may be further improved.

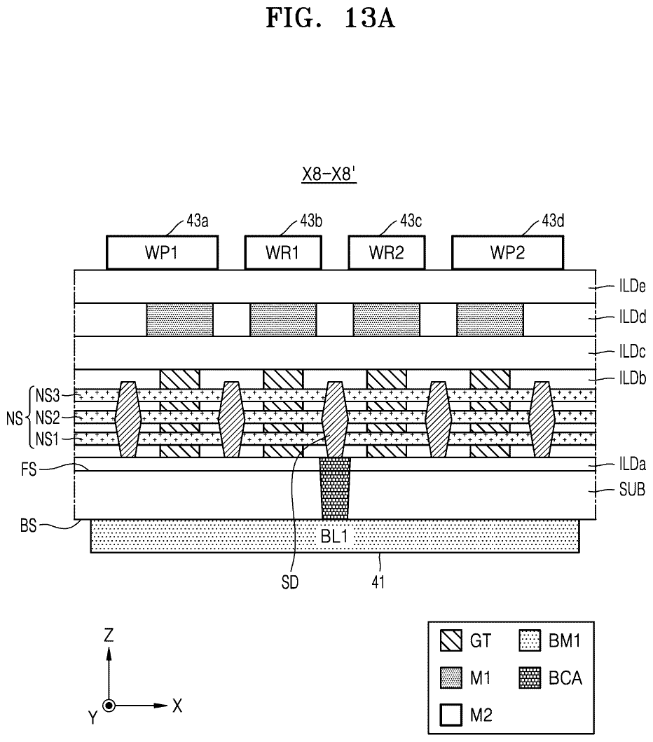

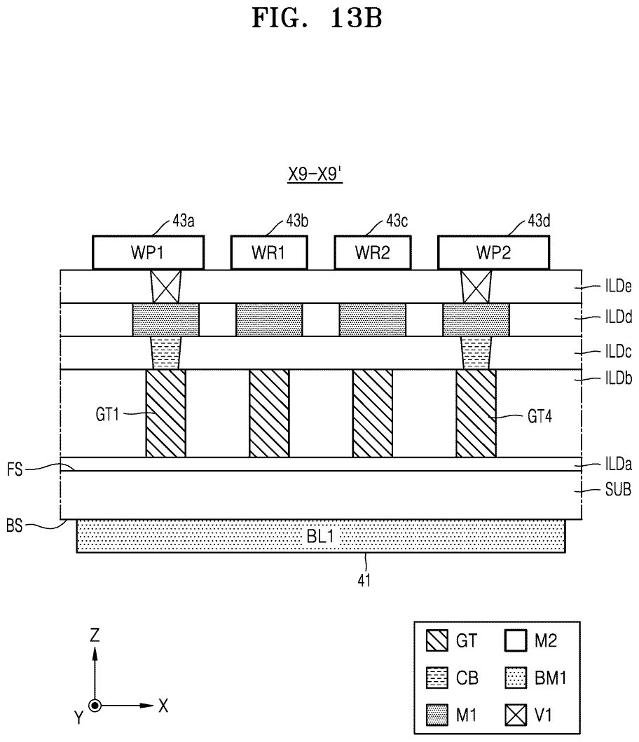

FIG. 12 illustrates a layout of an integrated circuit 40 according to some implementations. FIG. 13A is a cross-sectional view of the integrated circuit 40 of FIG. 12 taken along line X8-X8′ in FIG. 12, according to some implementations, and FIG. 13B is a cross-sectional view of the integrated circuit 40 of FIG. 12 taken along line X9-X9′ in FIG. 12, according to some implementations.

Referring to FIGS. 12 and 13A-13B, the integrated circuit 40 may include the active region RX, the gate lines GT, the source/drain contacts CA, the gate contacts CB, the second vias V1, the first front side wiring layer M1, the second front side wiring layer M2, the backside wiring layer BM1, and backside source/drain contact BCA. The integrated circuit 40 according to some implementations may correspond to a modified example of the integrated circuit 10 of FIG. 1, and the descriptions given on with reference to FIGS. 1 through 6C may also be applied to the integrated circuit 40.

In some implementations, the backside wiring layer BM1 may transfer the bit line BL signal to the OTP bit cell via the backside source/drain contacts BCA, and the first and second front side wiring layers M1 and M2 may transfer the program word line WLP signal and the read word line WLR signal to the OTP bit cell via the gate contacts CB and the second vias V1.

The gate contacts CB may be arranged on the gate lines GT1 through GT4, respectively. The source/drain contacts CA may each extend above the active region RX in the second direction Y. The first front side wiring layer M1 may include front side wiring patterns 42a through 42d extending in the second direction Y above the gate lines GT1 through GT4. The first front side wiring layer M1 may be connected to the gate lines GT1 through GT4 via the gate contacts CB. For example, the first front side wiring layer M1 may include the front side wiring pattern 42a above the gate line GT1, the front side wiring pattern 42b above the gate line GT2, the front side wiring pattern 42c above the gate line GT3, and the front side wiring pattern 42d above the gate line GT4. The width and/or length of the front side wiring patterns 42a through 42d included in the first front side wiring layer M1 may vary according to different implementations.

The second front side wiring layer M2 may include the front side wiring lines 43a through 43d extending in the second direction Y above the first front side wiring layer M1. The second front side wiring layer M2 may be connected to the first front side wiring layer M1 via the second vias V1. For example, the second front side wiring layer M2 may include the front side wiring line 43a above the front side wiring pattern 42a, the front side wiring line 43b above the front side wiring pattern 42b, the front side wiring line 43c above the front side wiring pattern 42c, and the front side wiring line 43d above the front side wiring pattern 42d. Widths and/or lengths of the front side wiring lines 43a through 43d included in the second front side wiring layer M2 may vary according to different implementations.

The backside wiring layer BM1 may include a backside wiring line 41 extending in the first direction X. The backside source/drain contacts BCA may be arranged above the backside wiring layer BM1, and may extend in the vertical direction Z. In some implementations, the backside source/drain contact BCA may overlap the active region RX. The backside wiring line 41 may be connected to the source/drain region SD via the backside source/drain contact BCA. For example, the source/drain region SD may correspond to a drain of a read transistor of the first OTP bit cell (BC1 in FIG. 4) and a drain of the second OTP bit cell (BC2 in FIG. 4). In this manner or another manner, the first and second OTP bit cells BC1 and BC2 may share the source/drain region SD.

For example, the front side wiring line 43a may receive the first program word line signal WP1. The front side wiring line 43a may be connected to the front side wiring pattern 42a via the second via V1, and the front side wiring pattern 42a may be connected to the gate line GT1 via the gate contact CB. For example, the front side wiring line 43b may receive the first read word line signal WR1. The front side wiring line 43b may be connected to the front side wiring pattern 42b via the first via V1, and the front side wiring pattern 42b may be connected to the gate line GT2 via the gate contact CB.

For example, the front side wiring line 43c may receive the second read word line signal WR2. The front side wiring line 43c may be connected to the front side wiring pattern 42c via the first via V1, and the front side wiring pattern 42c may be connected to the gate line GT3 via the gate contact CB. For example, the front side wiring line 43d may receive the second program word line signal WP2. The front side wiring line 43d may be connected to the front side wiring pattern 42d via the first via V1, and the front side wiring pattern 42d may be connected to the gate line GT4 via the gate contact CB.

According to some implementations, the first bit line BL1 signal may be supplied to the first and second OTP bit cells BC1 and BC2 via the DBC structure. Accordingly, the IR drop of the first bit line BL1 signal may be reduced, and as a result, the performance of the integrated circuit 40 may be improved. In addition, according some implementations, by arranging the bit line signal wiring in the backside wiring layer BM1 (e.g., as opposed to in the front side wiring layer), the wiring width of the front side wiring line included in the front side wiring layer may be increased. For example, the wiring width of each of the program word line signal wiring, that is, the front side wiring lines 43a and 43d and the read word line signal wiring, that is, the front side wiring lines 43b and 43c may be increased, and as a result, resistance reduction of the program word line and the read word line may further improve the performance of the integrated circuit 40.

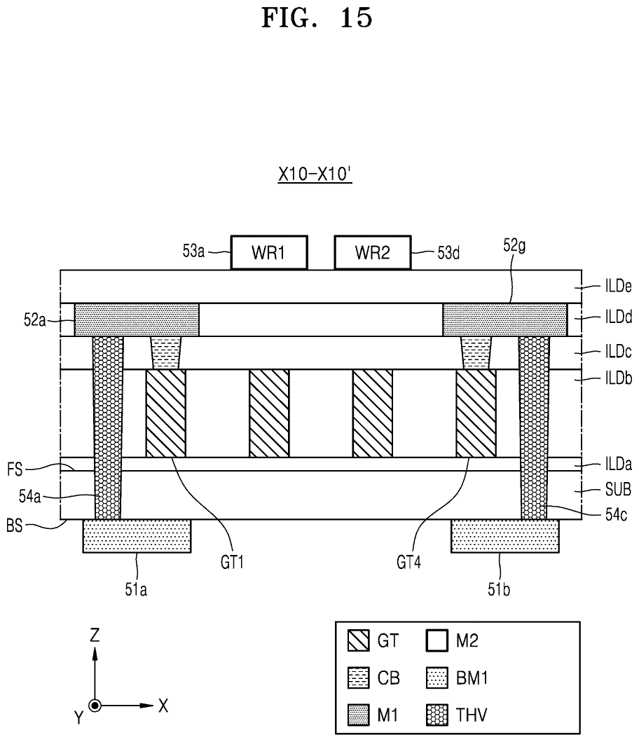

FIG. 14 illustrates a layout of the integrated circuit 50 according to some implementations. FIG. 15 is a cross-sectional view of the integrated circuit 50 of FIG. 14 taken along line X10-X10′ in FIG. 14.

Referring to FIGS. 14 and 15 together, the integrated circuit 50 may include the active region RX, the gate lines GT, the source/drain contacts CA, the gate contacts CB, the first via VA, the second vias V1, the first front side wiring layer M1, the second front side wiring layer M2, the backside wiring layer BM1, and through electrodes THV. The integrated circuit 50 according to some implementations may correspond to a modified example of the integrated circuit 10 of FIG. 1, and the descriptions given on with reference to FIGS. 1 through 6C may also be applied to the integrated circuit 50. In some implementations, the through electrodes THV may correspond to a power tap cell (PTC) or a small PTC (sPTC).

In some implementations, the backside wiring layer BM1 may transfer the program word line WLP signal to the OTP bit cell via the through electrodes THV, and the first and second front side wiring layers M1 and M2 may transfer the read word line WLR signal to the OTP bit cell via the gate contacts CB and the second vias V1, and may transfer the bit line BL signal to the OTP bit cell via the first and second vias VA and V1.

The gate contacts CB may be arranged on the gate lines GT1 through GT4, respectively. The source/drain contacts CA may each extend above the active region RX in the second direction Y. The first front side wiring layer M1 may include the front side wiring patterns 52a through 52i arranged above the gate lines GT1 through GT4. The first front side wiring layer M1 may be connected to the gate lines GT1 through GT4 via the gate contacts CB. For example, the first front side wiring layer M1 may include the front side wiring patterns 52a and 52b above the gate line GT1, the front side wiring patterns 52c and 52d above the gate line GT2, the front side wiring patterns 52e and 52f above the gate line GT3, and the front side wiring pattern 52g and 52h above the gate line GT4. In addition, the first front side wiring layer M1 may further include the front side wiring pattern 52i connected to the source/drain contact CA between the gate lines GT2 and GT3 via the first via VA. The width and/or length of the front side wiring patterns 52a through 52i included in the first front side wiring layer M1 may vary according to different implementations.

The second front side wiring layer M2 may include front side wiring lines 53a and 53b arranged above the first front side wiring layer M1. The second front side wiring layer M2 may be connected to the first front side wiring layer M1 via the second vias V1. For example, the second front side wiring layer M2 may include the front side wiring line 53a above the front side wiring patterns 52c and 52d, and the front side wiring line 53b above the front side wiring patterns 52e and 52f. Widths and/or lengths of the front side wiring lines 53a and 53b included in the second front side wiring layer M2 may vary according to different implementations.

The backside wiring layers BM1 may include backside wiring lines 51a and 51b spaced apart from each other in the first direction X and each extending in the second direction Y. The through electrodes THV may be arranged above the backside wiring layer BM1, and may extend in the vertical direction Z. In some implementations, the through electrodes THV may not overlap the active region RX. For example, the through electrodes THV may include through electrodes 54a and 54b above the backside wiring line 51a and through electrodes 54c and 54d above the backside wiring line 51b.

The through electrodes 54a and 54b may be arranged above the backside wiring line 51a. The backside wiring line 51a may be connected to the front side wiring pattern 52a via the through electrode 54a, and may be connected to the front side wiring pattern 52b via the through electrode 54b. Therefore, the gate line GT1 may be connected to the backside wiring line 51a via the gate contact CB, the front side wiring patterns 52a and 52b, and the through electrodes 54a and 54b. For example, the gate line GT1 may receive the first program word line signal WP1 from the backside wiring line 51a.

The through electrodes 54c and 54d may be arranged on the backside wiring line 51b. The backside wiring line 51b may be connected to the front side wiring pattern 52g via the through electrode 54c, and may be connected to the front side wiring pattern 52h via the through electrode 54d. Accordingly, the gate line GT4 may be connected to the backside wiring line 51b via the gate contact CB, the front side wiring pattern 52g and 52h, and the through electrodes 54c and 54d. For example, the gate line GT4 may receive the second program word line signal WP2 from the backside wiring line 51b.

According to some implementations, the first and second OTP bit cells BC1 and BC2 may receive the first and second program word line signals WP1 and WP2 via a through electrode structure. Accordingly, the IR drop of the first and second program word line signals WP1 and WP2 may be reduced, and as a result, the performance of the integrated circuit 50 may be improved. In addition, according to some implementations, by arranging the program word line signal wiring in the backside wiring layer BM1 (e.g., as opposed to in the front side wiring layer), the wiring width of the front side wiring line included in the front side wiring layer may be increased. For example, the wiring width of each of the read word line signal wirings included in the second front side wiring layer M2, e.g., the front side wiring lines 53a and 53b, may be increased, and as a result, the resistance reduction of the read word line may further improve the performance of the integrated circuit 50.

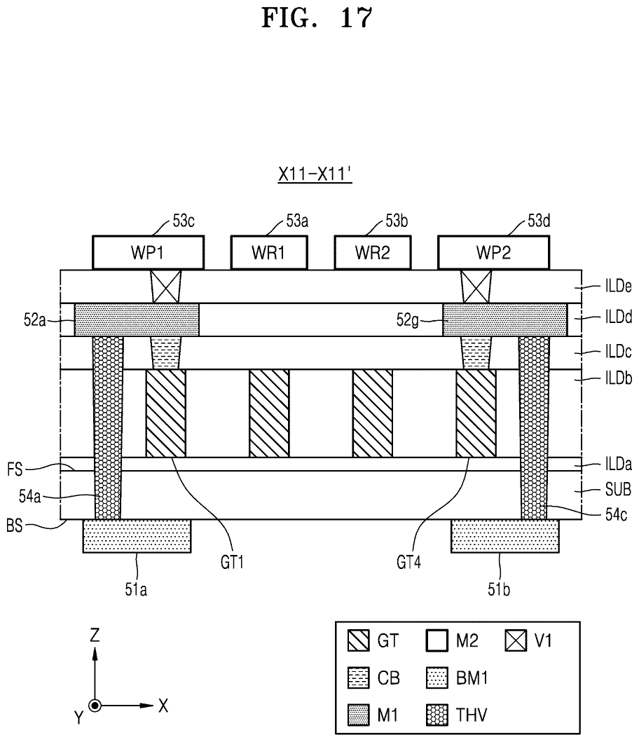

FIG. 16 illustrates a layout of the integrated circuit 50a according to some implementations. FIG. 17 is a cross-sectional view of the integrated circuit 50a of FIG. 17 taken along line X11-X11′ in FIG. 16.

Referring to FIGS. 16 and 17 together, the integrated circuit 50a may correspond to a modified example of the integrated circuit 50 of FIG. 14. The integrated circuit 50a may include the active region RX, the gate lines GT, the source/drain contacts CA, the gate contacts CB, the first via VA, the second vias V1, the first front side wiring layer M1, the second front side wiring layer M2, the backside wiring layer BM1, and the through electrodes THV.

In some implementations, the backside wiring layer BM1 may transfer the program word line WLP signal to the OTP bit cell via the through electrodes THV, and the first and second front side wiring layers M1 and M2 may transfer the program word line WLP signal and the read word line WLR signal to the OTP bit cell via the gate contacts CB and the second vias V1, and may transfer the bit line BL signal to the OTP bit cell via the first and second vias VA and V1.

The gate contacts CB may be arranged on the gate lines GT1 through GT4, respectively. The source/drain contacts CA may each extend above the active region RX in the second direction Y. The second front side wiring layer M2 may include front side wiring lines 53a through 53d arranged above the first front side wiring layer M1. The second front side wiring layer M2 may be connected to the first front side wiring layer M1 via the second vias V1. For example, the second front side wiring layer M2 may include the front side wiring line 53c above the front side wiring patterns 52a and 52b, the front side wiring line 53a above the front side wiring patterns 52c and 52d, the front side wiring line 53b above the front side wiring patterns 52e and 52f, and the front side wiring line 53d above the front side wiring patterns 52g and 52h. Widths and/or lengths of the front side wiring lines 53a through 53d included in the second front side wiring layer M2 may vary according to different implementations.

According to some implementations, the first and second program word line signals WP1 and WP2 may be supplied to the first and second OTP bit cells BC1 and BC2 via the through electrode structure, respectively, and in addition, the first and second program word line signals WP1 and WP2 may be supplied to the first and second OTP bit cells BC1 and BC2 via the first and second front side wiring layers M1 and M2, respectively. Accordingly, the IR drop of the first and second program word line signals WP1 and WP2 may be reduced, and as a result, the performance of the integrated circuit 50a may be improved.

FIGS. 18A through 18D respectively illustrate devices according to some implementations.

For example, FIG. 18A illustrates a FinFET 60a, FIG. 18B illustrates a gate-all-around FET (GAAFET) 60b, FIG. 18C illustrates a multi-bridge channel FET (MBCFET) 60c, and FIG. 18D illustrates a vertical (V) FET (VFET) 60d. For convenience of illustration, FIGS. 18A through 18C illustrate a state in which one of two source/drain regions is removed, and FIG. 18D illustrates a cross-section of the VFET 60d taken along a plane which is in parallel with a plane including the second direction Y and the vertical direction Z that penetrates a channel CH of the VFET 60d.

Referring to FIG. 18A, the FinFET 60a may be formed by a fin-shaped active pattern extending in the first direction X and a gate G extending in the second direction Y between shallow trench isolations STI. Source/drains S/D may be formed at both sides of the gate G, and accordingly, the source and the drain may be spaced apart from each other in the first direction X. An insulating layer may be formed between the channel CH and the gate G. In some implementations, the FinFET 60a may be formed by a plurality of active patterns apart from each other in the second direction Y and the gate G.

Referring to FIG. 18B, the GAAFET 60b may be formed by active patterns apart from each other in the vertical direction Z and extending in the first direction X, that is, nanowires, and the gate G extending in the second direction Y. The source/drains S/D may be formed on both sides of the gate G, and accordingly, the source and the drain may be spaced apart from each other in the first direction X. An insulating layer may be formed between the channel CH and the gate G. The number of nanowires included in the GAAFET 60b is not limited to the number illustrated in FIG. 18B.

Referring to FIG. 18C, the MBCFET 60c may be formed by active patterns apart from each other in the vertical direction Z and extending in the first direction X, e.g., nanosheets, and the gate G extending in the second direction Y. The source/drains S/D may be formed on both sides of the gate G, and accordingly, the source and the drain may be spaced apart from each other in the first direction X. An insulating layer may be formed between the channel CH and the gate G. The number of nanosheets included in the MBCFET 60c is not limited to the number illustrated in FIG. 18C.

Referring to FIG. 18D, the VFET 60d may include a top source/drain T_S/D and a bottom source/drain B_S/D apart from each other in the vertical direction Z with the channel CH therebetween. The VFET 60d may include the gate G surrounding the circumference of the channel CH between the top source/drain T_S/D and the bottom source/drain B_S/D. An insulating layer may be formed between the channel CH and the gate G.

However, transistors according to implementations of the present disclosure are not limited to structures described with respect to FIGS. 18A-18D. For example, because the nanosheets for a P-type transistor are separated from the nanosheets for an N-type transistor by a dielectric wall, an integrated circuit may include a fork FET (ForkFET) having a structure, in which the N-type transistor and the P-type transistor are further close to each other. In addition, an integrated circuit may include a FET, such as a complementary (C) FET (CFET), a negative capacitance (NC) (NCFET), and a carbon nanotube (CN) (CNTFET), and/or a bipolar junction transistor.

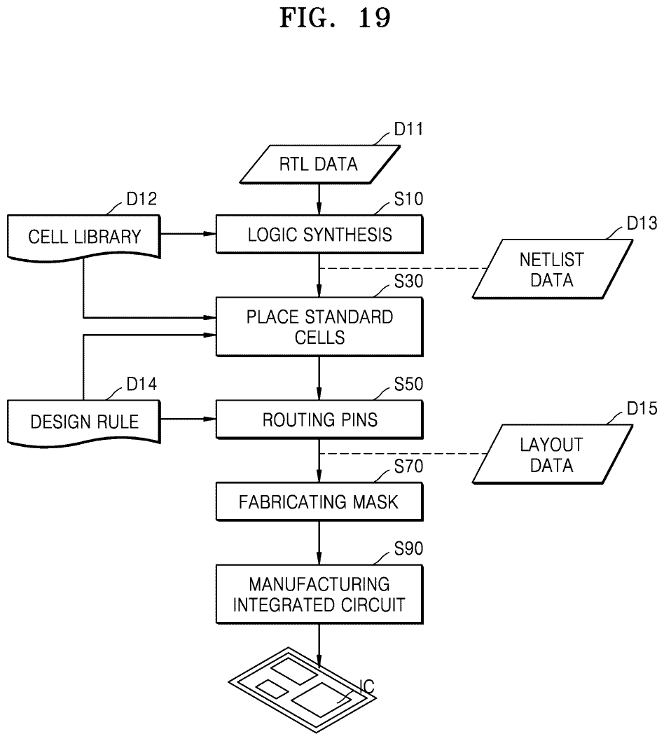

FIG. 19 is a flowchart illustrating a method of manufacturing an integrated circuit, according to some implementations.

Referring to FIG. 19, a method according to the present disclosure may be a method of manufacturing an integrated circuit (IC) including standard cells, and may include a plurality of operations S10, S30, S50, S70, and S90. A cell library (or standard cell library) D12 may include information about standard cells, such as function information, characteristics information, and layout information. In some implementations, the cell library D12 may define tap cells and dummy cells as well as functional cells generating an output signal from an input signal. In some implementations, the cell library D12 may define memory cells and dummy cells having the same footprint. Design rule D14 may include requirements to be complied with by the layout of the integrated circuit IC. For example, the design rule D14 may include requirements for the distance between patterns on the same layer, a minimum width of a pattern, a routing direction of a wiring layer, etc. In some implementations, the design rule D14 may define a minimum separation distance on the same track of a wiring layer.

In operation S10, a logic synthesis operation of generating netlist data D13 from register transfer level (RTL) data D11 may be performed. For example, a semiconductor design tool (for example, a logic synthesis tool) may generate the netlist data D13 including a bitstream or a netlist, by performing a logical synthesis with reference to the cell library D12 from the RTL data D11 that is prepared in a hardware description language (HDL), such as very high speed integrated circuit (VHSIC) hardware description language (VHDL) and Verilog. The netlist data D13 may correspond to an input of placement and routing to be described below.

In operation S30, the standard cells may be arranged. For example, a semiconductor design tool (for example, a placement and routing (P&R) tool) may arrange the standard cells used in the netlist data D13 with reference to the cell library D12. In some implementations, a semiconductor design tool may arrange a standard cell in a row extending in the X-axis or Y-axis direction, and the arranged standard cell may receive power from a power rail extending along the boundary of the row.

In operation S50, pins of the standard cells may be routed. For example, a semiconductor design tool may generate interconnections electrically connecting output pins to input pins of the arranged standard cells, and may generate the layout data D15 defining the arranged standard cells and the generated interconnections. The interconnection may include vias of a via layer and/or a pattern of the wiring layer. The wiring layers may include a front side wiring layer arranged above a front side of a substrate and a backside wiring layer arranged on a backside of a substrate. Layout data D15 may have a format such as graphic design system information interchange (GDSII), and may have geometric information about cells and interconnections thereof. A semiconductor design tool may refer to the design rule D14 while routing pins of the cells. The layout data D15 may correspond to an arrangement and an output of routing. Operation S50 alone, or operations S30 and S50 comprehensively may be referred to as a method of designing an integrated circuit.

As illustrated in FIGS. 1 through 17, a front side wiring layer may transmit, to the OTP bit cell, at least one of a program word line signal, a read word line signal, and a bit line signal, and a backside wiring layer may transmit, to the OTP bit cell, at least one of a program word line signal, a read word line signal, and a bit line signal. In this case, a backside wiring layer may reduce a signal transfer path by transferring a signal to the OTP bit cell via backside gate contacts overlapping an active region, and accordingly, the performance of an integrated circuit may be improved.

As described herein, by implementing the OTP bit cell by utilizing the front side wiring lines and the backside wiring lines, an integrated circuit may reduce the IR drop of signals applied to the OTP bit cell. In addition, by receiving the program word line signal, the read word line signal, and/or the bit line signal from the front side wiring lines and the backside wiring lines, an operation speed of the OTP bit cell may be improved, and as a result, the performance of the integrated circuit may be improved. Furthermore, by increasing the widths of the front side wiring lines arranged above the OTP bit cell, the IR drop of a signal applied to the front side wiring lines may be further reduced, and as a result, the performance of the integrated circuit may be further improved.

In addition, according to some implementations described herein, by using the backside wiring lines, the integrated circuit may reduce routing complexity of the first front side wiring layer, and improve power, performance, and area (PPA) of the integrated circuit. Furthermore, by having the DBC structure, in which a gate line or a source/drain region is directly connected to the backside wiring line of a backside wiring layer, the PPA of the integrated circuit may be further improved.

In operation S70, an operation of fabricating a mask may be performed. For example, in photolithography, an optical probability correction (OPC) process for correcting a distortion phenomenon, such as refraction due to characteristics of light, may be applied to the layout data D15. Patterns on the mask may be defined to form patterns arranged on a plurality of layers based on data, to which the OPC has been applied, and at least one mask (or a photomask) for forming patterns of each of the plurality of layers may be manufactured. In some implementations, the layout of the integrated circuit IC may be limitedly modified in operation S70, and the limited modification on the integrated circuit IC in operation S70 may be a post process for optimizing the structure of the integrated circuit IC, which may be referred to as a design polishing process.

In operation S90, an operation of manufacturing the integrated circuit IC may be performed. For example, the integrated circuit IC may be fabricated by patterning the plurality of layers by using at least one mask fabricated in operation S70. A front-end-of-line (FEOL) process may include, for example, planarizing and cleaning of a wafer, forming a trench, forming a well, forming a gate line, and forming a source and drain. By using the FEOL process, individual devices, for example, a transistor, a capacitor, a resistor, or the like may be formed on a substrate. In addition, a back-end-of-line (BEOL) process may include, for example, silicidating a gate region, a source region, and a drain region, adding a dielectric material, planarizing, forming a hole, adding a metal layer, forming a via, forming a passivation layer, etc. By using the BEOL process, individual devices, for example, a transistor, a capacitor, a resistor, or the like may be interconnected. In some implementations, a middle-of-line (MOL) process may be performed between the FEOL and BEOL processes, and contacts may be formed on individual devices. Next, the integrated circuit IC may be packaged in a semiconductor package, and used as a component of various applications.

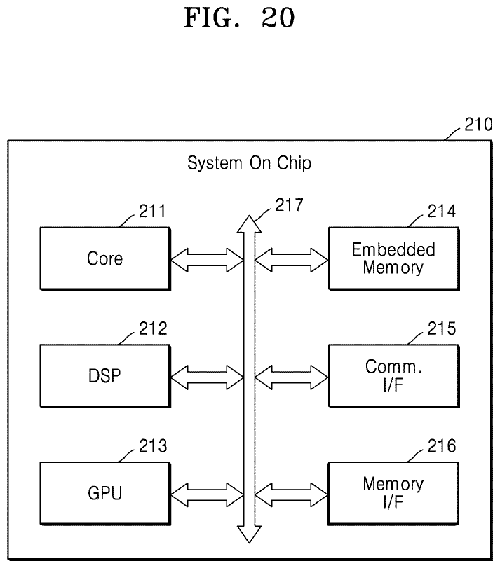

FIG. 20 is a block diagram of a system on chip 210 according to some implementations.

Referring to FIG. 20, the system on chip (SoC) 210 may be referred to as an integrated circuit on which components of a computing system or another electronic system are integrated. For example, an application processor (AP), as an example of the SoC 210, may include a processor and components for other functions. The SoC 210 may include a core 211, a digital signal processor (DSP) 212, a graphics processing unit (GPU) 213, an embedded memory 214, a communication (comm.) interface (I/F) 215, and a memory I/F 216. Components of the SoC 210 may communicate with each other via a bus 217.

The core 211 may execute commands, and control operations of components included in the SoC 210. For example, the core 211 may drive an operating system by executing a series of commands, and execute applications on the operating system. The DSP 212 may generate useful data by processing a digital signal, for example, a digital signal provided by the comm. I/F 215.

The GPU 213 may also generate data for an image output by a display device from image data provided by the embedded memory 214 or the memory I/F 216, and may also encode the image data. In some implementations, the integrated circuit described above with reference to the drawings may be included in the core 211, the DSP 212, the GPU 213, and/or the embedded memory 214.

The embedded memory 214 may store data needed for operations of the core 211, the DSP 212, and the GPU 213. The comm. I/F 215 may provide a communication network or an interface for one-to-one communication. The memory I/F 216 may provide an I/F for an external memory of the SoC 210, for example, DRAM, flash memory, etc.

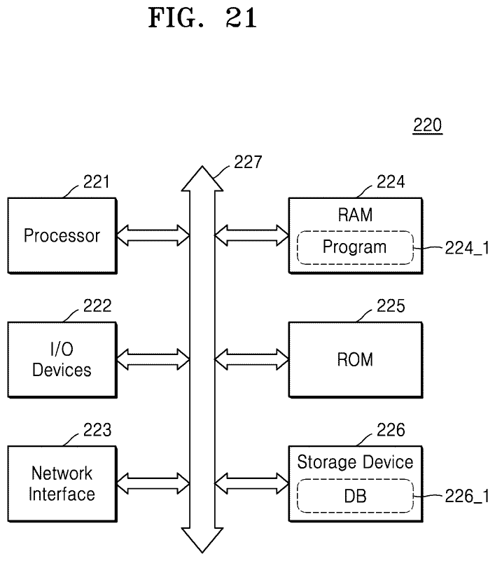

FIG. 21 is a block diagram of a computing system 220 including a memory storing a program, according to some implementations.

Referring to FIG. 21, a method is illustrated of designing an integrated circuit according to some implementations, for example, at least a portion of operations of the flowchart described above may be performed by the computing system 220. The computing system 220 may include a processor 221, input/output (I/O) devices 222, a network interface 223, RAM 224, a read-only memory (ROM) 225, and a storage device 226. The processor 221, the I/O devices 222, the network interface 223, the RAM 224, the ROM 225, and the storage device 226 may be connected to a bus 227, and may communicate with each other via the bus 227.

The processor 221 may be referred to as a processing unit, and may include at least one core, such as a micro-processor, an application processor (AP), a digital signal processor (DSP), and a GPU, which is capable of executing an arbitrary command set (for example, Intel Architecture-32 (IA-32)), 64-bit extension IA-32, x86-64, PowerPC, scalable processor architecture (SPARC), a microprocessor without interlocked pipeline stages (MIPS), an Acorn reduced instruction set computer (RISC) machine (ARM), Intel Architecture-62 (IA-64), etc.). For example, the processor 221 may access a memory, that is, the RAM 224 or the ROM 225 via the bus 227, and may execute commands stored in the RAM 224 or the ROM 225.

The RAM 224 may store a program 224_1 for a method of designing an integrated circuit according to some implementations, or at least a portion thereof, and the program 224_1 may cause the processor 221 to perform at least a portion of operations included in the method of designing an integrated circuit, for example, the methods in FIG. 19. In other words, the program 224_1 may include a plurality of commands executable by the processor 221, and the plurality of commands included in the program 224_1 may cause the processor 221 to perform at least a portion of operations included in the flowchart described above.

The storage device 226 may not lose stored data even when the power supplied to the computing system 220 is cut off. The storage device 226 may also store the program 224_1 according to some implementations, and before the program 224_1 is executed by the processor 221, the program 224_1 or at least a portion thereof may be loaded into the RAM 224 from the storage device 226. Alternatively, the storage device 226 may store a file written in a program language, and a program 224_1 generated from the file by a compiler or the like or at least a portion thereof may be loaded into the RAM 224. In addition, the storage device 226 may store database (DB) 226_1, the DB 226_1 may include information required for designing an integrated circuit, for example, information about designed blocks, the cell library D12 in FIG. 19, and/or the design rule D14.

The storage device 226 may also store data to be processed by the processor 221 or data processed by the processor 221. In other words, the processor 221 may, according to the program 224_1, generate data by processing the data stored in the storage device 226, and may store the generated data in the storage device 226. For example, the storage device 226 may store the RTL data D11, the netlist data D13, and/or the layout data D15 in FIG. 19.

The I/O devices 222 may include an input device, such as a keyboard and a pointing device, and may include an output device, such as a display device and a printer. For example, the user may also, via the I/O devices 222, trigger execution of the program 224_1 by using the processor 221, may also input the RTL data D11 and/or the netlist data D13 in FIG. 19, and may also identify the layout data D15 in FIG. 19. The network interface 223 may provide an access to a network outside the computing system 220. For example, the network may include a plurality of computing systems and communication links, and the communication links may include wired links, optical links, wireless links, or any other types of links.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples have been particularly shown and described, it will be understood that various changes in form and details may be made therein without departing from the spirit and scope of the following claims.

What is claimed is:

1. An integrated circuit comprising:
a one-time programmable bit cell including a program transistor and a read transistor arranged on an active region on a front side of a substrate;
a first backside gate contact extending through the substrate in a vertical direction and overlapping the active region;
a backside wiring layer arranged on a backside of the substrate and electrically connected to a first gate of the program transistor via the first backside gate contact, the backside wiring layer configured to transfer a program word line signal to the first gate; and
a front side wiring layer arranged above the front side of the substrate and including a first front side wiring pattern electrically connected to a second gate of the read transistor, the first front side wiring pattern configured to transfer a read word line signal to the second gate.

2. The integrated circuit of claim 1, wherein the front side wiring layer comprises a second front side wiring pattern electrically connected to the first gate, the front side wiring layer configured to transfer the program word line signal to the first gate.

3. The integrated circuit of claim 2, comprising a first gate contact arranged on the first gate,
wherein the second front side wiring pattern is electrically connected to the first gate via the first gate contact.

4. The integrated circuit of claim 1, wherein the front side wiring layer comprises a third front side wiring pattern configured as a bit line connected to a source/drain of the read transistor.

5. The integrated circuit of claim 1, wherein the active region extends in a first direction, and
wherein the first gate and the second gate are arranged above the active region and each extend in a second direction crossing the first direction.

6. The integrated circuit of claim 5, comprising at least one second backside gate contact extending through the substrate in the vertical direction,
wherein the at least one second backside gate contact is spaced laterally apart from the active region.

7. The integrated circuit of claim 6, wherein the backside wiring layer extends in the second direction and is electrically connected to the first gate via the first backside gate contact and the at least one second backside gate contact.

8. The integrated circuit of claim 1, comprising a second gate contact arranged on the second gate,
wherein the first front side wiring pattern is electrically connected to the second gate via the second gate contact.

9. An integrated circuit comprising:
a one-time programmable bit cell including a program transistor and a read transistor arranged on an active region on a front side of a substrate;
a front side wiring layer arranged above the front side of the substrate and including a first front side wiring pattern electrically connected to a first gate of the program transistor, the front side wiring layer configured to transfer a program word line signal to the first gate;
a first backside gate contact extending through the substrate in a vertical direction and overlapping the active region; and
a backside wiring layer arranged on a backside of the substrate and electrically connected to a second gate of the read transistor via the first backside gate contact, the backside wiring layer configured to transfer a read word line signal to the second gate.

10. The integrated circuit of claim 9, wherein the front side wiring layer comprises a second front side wiring pattern electrically connected to the second gate and configured to transfer the read word line signal to the second gate.

11. The integrated circuit of claim 9, wherein the front side wiring layer comprises a third front side wiring pattern configured as a bit line, the third front side wiring pattern electrically connected to a source/drain of the read transistor.

12. The integrated circuit of claim 9, wherein the active region extends in a first direction, and
wherein the first gate and the second gate are arranged above the active region and each extends in a second direction crossing the first direction.

13. The integrated circuit of claim 12, comprising at least one second backside gate contact extending through the substrate in the vertical direction,
wherein the at least one second backside gate contact is spaced laterally apart from the active region.

14. The integrated circuit of claim 13, wherein the backside wiring layer extends in the second direction and is electrically connected to the second gate via the first backside gate contact and the at least one second backside gate contact.

15. An integrated circuit comprising:
a one-time programmable bit cell including a program transistor and a read transistor arranged on an active region on a front side of a substrate;
a front side wiring layer arranged above the front side of the substrate, the front side wiring layer including
a first front side wiring pattern electrically connected to a first gate of the program transistor, the first front side wiring pattern configured to transfer a program word line signal to the first gate, and
a second front side wiring pattern electrically connected to a second gate of the read transistor, the second front side wiring pattern configured to transfer a read word line signal to the second gate;
a through via extending in a vertical direction through the substrate; and
a backside wiring layer arranged on a backside of the substrate and electrically connected to the first front side wiring pattern via the through via.

16. The integrated circuit of claim 15, comprising a first gate contact arranged on the first gate,
wherein the first front side wiring pattern is electrically connected to the first gate via the first gate contact.

17. The integrated circuit of claim 15, wherein the front side wiring layer further comprises a third front side wiring pattern configured as a bit line, the third front side wiring pattern electrically connected to a source/drain of the read transistor.

18. The integrated circuit of claim 15, wherein the through via is spaced laterally apart from the active region.

19. The integrated circuit of claim 15, wherein the active region extends in a first direction, and
wherein the first gate and the second gate are arranged above the active region and each extend in a second direction crossing the first direction.

20. The integrated circuit of claim 15, comprising a second gate contact arranged on the second gate,
wherein the second front side wiring pattern is electrically connected to the second gate via the second gate contact.
